(19) United States
(12) Patent Application Publication
(10) Pub. No.: US 2026/0040942 A1
(43) Pub. Date: Feb. 5, 2026

(54) HYBRID LAMINATE AND HEAT DISSIPATION OF STACKED PACKAGE

(71) Applicant: Qorvo US, Inc., Greensboro, NC (US)

(72) Inventors: MD Hasnine, Richardson, TX (US); Peter Haase, Richardson, TX (US)

(21) Appl. No.: 19/262,793

(22) Filed: Jul. 8, 2025

Related U.S. Application Data
(60) Provisional application No. 63/678,896, filed on Aug. 2, 2024.

(51) Int. Cl. H01L 23/34; H01L 23/00; H01L 23/31; H01L 23/498; H01L 25/04; H04B 1/40

(52) U.S. Cl. CPC H01L 23/34; H01L 23/3107; H01L 23/49811; H01L 23/49816; H01L 25/04; H04B 1/40; H01L 24/16; H01L 2224/16225

(57) ABSTRACT

The present disclosure relates to a microelectronics package with a stacked arrangement, which enables efficient thermal paths for both top-side cooling and bottom-side cooling, and a process for making the same. The disclosed microelectronics package includes a carrier board, a first sub-package attached to the carrier board, and a second sub-package vertically stacked with the first sub-package. Herein, each of the first sub-package and the second sub-package includes a substrate, a flip-chip die attached to the corresponding substrate, and a heat spreader attached to the corresponding substrate and completely covering and thermally connected to the corresponding flip-chip die. The second sub-package is thermally connected to the heat spreader of the first sub-package. The substrate within the second sub-package is different from and has a higher thermal conductivity than the substrate within the first sub-package, and is thermally connected to the flip-chip die of the second sub-package.

### RELATED APPLICATIONS

This application claims the benefit of provisional patent application Ser. No. 63/678,896, filed Aug. 2, 2024, the disclosure of which is hereby incorporated herein by reference in its entirety.

### FIELD OF THE DISCLOSURE

The present disclosure relates to a microelectronics package with a stacked arrangement, which enables efficient thermal paths for both top-side cooling and bottom-side cooling, and a process for making the same.

### BACKGROUND

With the popularity of portable electronic products in both consumer and military applications, three-dimensional (3D) packaging techniques, such as stacked-die assemblies and package on package (POP) structures, are becoming more and more attractive in microelectronics packages to achieve electronics densification in a small footprint. Yet, as electronic designs increasingly embrace 3D packaging, thermal issues become more pronounced. The stacked-die assemblies or POP structures lead to increased heat generation, resulting in higher temperatures that pose challenges for thermal management.

On the other hand, with faster switching speed, higher breakdown strength, and lower on-resistance, high-power radio frequency (RF) devices based on gallium nitride (GaN)/gallium arsenide (GaAs) technology significantly outperform silicon-based devices. It is desirable to decrease gate spacing of GaN/GaAs devices to further enhance the breakdown voltage and maximum output power. As the gate spacing of the GaN/GaAs devices reduces, there is an increase in concentrated heat flux in the die bodies. Effectively managing device heating and controlling junction temperatures becomes essential, given their potential to negatively impact performance and reliability. In the case of the high-power RF devices attached to a package substrate, the ability to dissipate large amounts of heat through the package substrate underneath the devices (bottom-side cooling) is limited. This limitation results in high thermal resistance, ultimately degrading the device's lifetime. In addition, depending solely on heat sinks attached to the package substrate has been proven insufficient for dissipating highly concentrated heat flux.

Accordingly, there remains a need for improved package designs for advanced thermal management solutions, so as to facilitate utilization of the wide bandgap semiconductors (GaN, GaAs, silicon carbide) in 3D packaging configurations.

### SUMMARY

The present disclosure relates to a microelectronics package with a stacked arrangement, which enables efficient thermal paths for both top-side cooling and bottom-side cooling, and a process for making the same. The disclosed microelectronics package includes a carrier board, a first sub-package attached to the carrier board via a number of electrical contacts, and a second sub-package vertically stacked with the first sub-package. Herein, the first sub-package includes a first substrate, a first flip-chip die attached to the first substrate, and a first heat spreader attached to the first substrate and completely covering and thermally connected to the first flip-chip die. The second sub-package, which is thermally connected to the first heat spreader of the first sub-package, includes a second substrate, a second flip-chip die attached to the second substrate, and a second heat spreader attached to the second substrate and completely covering the second flip-chip die. The second substrate is different from the first substrate and has a higher thermal conductivity than the first substrate. The second flip-chip die is thermally connected to both the second substrate and the second heat spreader.

In one embodiment of the microelectronics package, the first heat spreader includes a first lid and a first periphery fence that extends outwardly from the first lid and towards the first substrate and surrounds the first flip-chip die. The second heat spreader includes a second lid and a second periphery fence that extends outwardly from the second lid and towards the second substrate and surrounds the second flip-chip die.

In one embodiment of the microelectronics package, the first flip-chip die is attached to a top surface of the first substrate, while the first lid of the first heat spreader is formed over and thermally attached to a backside of the first flip-chip die, and the first periphery fence extends outwardly from a periphery of a bottom surface of the first lid and is attached to the top surface of the first substrate. A top surface of the first sub-package is a top surface of the first lid of the first heat spreader and is thermally connected to a bottom surface of the second sub-package.

In one embodiment of the microelectronics package, the second flip-chip die is attached to a top surface of the second substrate, while the second lid of the second heat spreader is formed over and thermally attached to a backside of the second flip-chip die, and the second periphery fence extends outwardly from a periphery of a bottom surface of the second lid and is attached to the top surface of the second substrate. The bottom surface of the second sub-package is a bottom surface of the second substrate.

In one embodiment of the microelectronics package, the bottom surface of the first lid of the first heat spreader is thermally attached to the backside of the first flip-chip die via a first sintered layer. The bottom surface of the second lid of the second heat spreader is thermally attached to the backside of the second flip-chip die via a second sintered layer. The second periphery fence of the second heat spreader is attached to the top surface of the second substrate via a sintered component. Herein, each of the first sintered layer, the second sintered layer, and the sintered component has a thermal conductivity larger than 60 W/m·K.

In one embodiment of the microelectronics package, the second flip-chip die is attached to a bottom surface of the second substrate, while the second lid of the second heat spreader is formed underneath and thermally attached to a backside of the second flip-chip die, and the second periphery fence extends outwardly from a periphery of a top surface of the second lid and is attached to the bottom surface of the second substrate. The bottom surface of the second sub-package is a bottom surface of the second lid of the second heat spreader.

In one embodiment of the microelectronics package, the bottom surface of the first lid of the first heat spreader is thermally attached to the backside of the first flip-chip die via the first sintered layer. The top surface of the second lid of the second heat spreader is thermally attached to the backside of the second flip-chip die via the second sintered layer. The second periphery fence of the second heat spreader is attached to the bottom surface of the second substrate via the sintered component. Herein, each of the first sintered layer, the second sintered layer, and the sintered component has a thermal conductivity larger than 60 W/m·K.

In one embodiment of the microelectronics package, the first substrate includes a substrate body formed of one or more organic materials, and a number of thermal substrate vias extending through the substrate body. Each of the thermal substrate vias is connected to a corresponding one of the electrical contacts. The bottom surface of the first lid of the first heat spreader is thermally attached to the backside of the first flip-chip die via the first sintered layer. The first periphery fence of the first heat spreader is thermally attached to the thermal substrate vias of the first substrate via the sintered component. Herein, each of the first sintered layer and the sintered component has a thermal conductivity larger than 60 W/m·K.

In one embodiment of the microelectronics package, the first periphery fence of the first heat spreader is composed of multiple discreate heat spreader legs with gaps in between, while the second periphery fence of the second heat spreader is composed of multiple discreate heat spreader legs with gaps in between.

According to one embodiment, the microelectronics package further includes a mold compound, which is formed over the first substrate and surrounds the first heat spreader and the second sub-package. In addition, the mold compound fills cavities between the first flip-chip die and the first heat spreader, and between the second flip-chip die and the second heat spreader.

In one embodiment of the microelectronics package, the first periphery fence is a continuous heat spreader wall, and the first flip-chip die is encapsulated by the first heat spreader. The second periphery fence is a continuous heat spreader wall, and the second flip-chip die is encapsulated by the second heat spreader.

According to one embodiment, the microelectronics package further includes a mold compound, which is formed over the first substrate and surrounds the first heat spreader and the second sub-package. The mold compound is not in contact with the first flip-chip die or the second flip-chip die.

In one embodiment of the microelectronics package, the second sub-package is thermally connected to the first heat spreader of the first sub-package via a package sintered layer with a thermal conductivity larger than 60 W/m·K.

In one embodiment of the microelectronics package, the first heat spreader and the second heat spreader are formed of silicon carbide.

In one embodiment of the microelectronics package, the first heat spreader is at least 1.5 times larger than the first flip-chip die in horizontal dimensions. The second heat spreader is at least 1.5 times larger than the second flip-chip die in horizontal dimensions.

In one embodiment of the microelectronics package, the first substrate is a laminate-based substrate, while the second substrate is a lead frame substrate.

In one embodiment of the microelectronics package, the electrical contacts are configured as a Ball Grid Array (BGA).

In one embodiment of the microelectronics package, the electrical contacts are configured as a Land Grid Array (LGA).

In one embodiment of the microelectronics package, the first flip-chip die includes a first die body, first interconnects extending outwardly from the first die body and coupled to the first substrate via first solder caps, respectively, and first die vias extending through the first die body and coupled to corresponding first interconnects, respectively. The second flip-chip die includes a second die body, second interconnects extending outwardly from the second die body and coupled to the second substrate via second solder caps, respectively, and second die vias extending through the second die body and coupled to corresponding second interconnects, respectively.

In one embodiment of the microelectronics package, the first die body includes gallium nitride (GaN), gallium arsenide (GaAs), or silicon, while the second die body includes GaN or GaAs.

In one embodiment of the microelectronics package, the first sub-package further includes a first underfilling material, which at least encapsulates each of the first solder caps. The second sub-package further comprises a second underfilling material, which at least encapsulates each of the second solder caps.

According to one embodiment, the microelectronics package further includes a heat sink, which resides over and is thermally connected to the second sub-package.

According to one embodiment, a communication device includes a control system, a baseband processor, receive circuitry, and transmit circuitry. Herein, at least one or any combination of the control system, the baseband processer, the transmit circuitry, and the receive circuitry is implemented in a microelectronics package, which includes a carrier board, a first sub-package, and a second sub-package. Herein, the first sub-package is attached to the carrier board via a number of electrical contacts and includes a first substrate, a first flip-chip die attached to the first substrate, and a first heat spreader attached to the first substrate and completely covering and thermally connected to the first flip-chip die. The second sub-package is vertically stacked with and thermally connected to the first heat spreader of the first sub-package. The second sub-package includes a second substrate, a second flip-chip die attached to the second substrate, and a second heat spreader attached to the second substrate and completely covering the second flip-chip die. The second substrate is different from the first substrate and has a higher thermal conductivity than the first substrate. Within the second sub-package, the second flip-chip die is thermally connected to both the second substrate and the second heat spreader.

According to one embodiment, a method of fabricating a microelectronics package starts with forming a first sub-package and a second sub-package. Herein, the first sub-package includes a first substrate, a first flip-chip die attached to the first substrate, and a first heat spreader attached to the first substrate and completely covering and thermally connected to the first flip-chip die. The second sub-package includes a second substrate, a second flip-chip die attached to the second substrate, and a second heat spreader attached to the second substrate and completely covering the second flip-chip die. The second substrate is different from the first substrate and has a higher thermal conductivity than the first substrate. Within the second sub-package, the second flip-chip die is thermally connected to both the second substrate and the second heat spreader. The second sub-package is then attached over the first sub-package, such that the second sub-package is thermally connected to the first heat spreader of the first sub-package.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure and, together with the description, serve to explain the principles of the disclosure.

FIGS. 1A-1B illustrate an exemplary microelectronics package with a stacked arrangement according to some embodiments of the present disclosure.

FIGS. 2A-2B illustrate an alternative configuration of the microelectronics package according to some embodiments of the present disclosure.

FIGS. 3-16B illustrate steps of a process of fabricating the microelectronics packages shown in FIGS. 1A and 1B according to some embodiments of the present disclosure.

FIGS. 17-21B illustrate steps of an alternative process of fabricating the microelectronics packages shown in FIGS. 2A and 2B according to some embodiments of the present disclosure.

FIG. 22 is a block diagram of a communication device, which may include the air-cavity package illustrated in FIGS. 1A, 1B, 2A, and 2B according to some embodiments of the present disclosure.

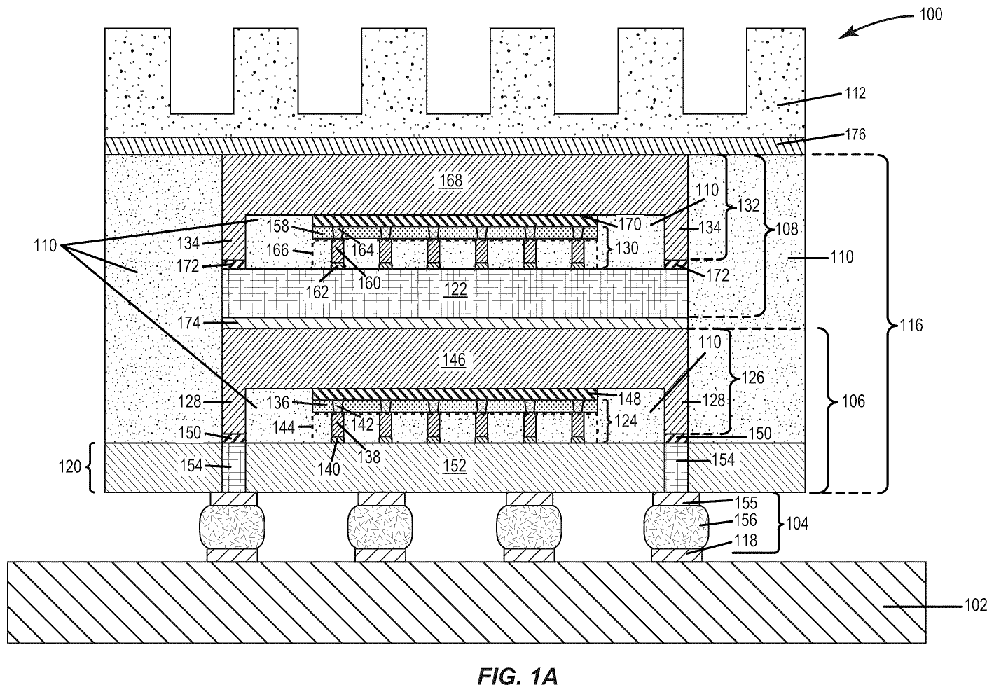

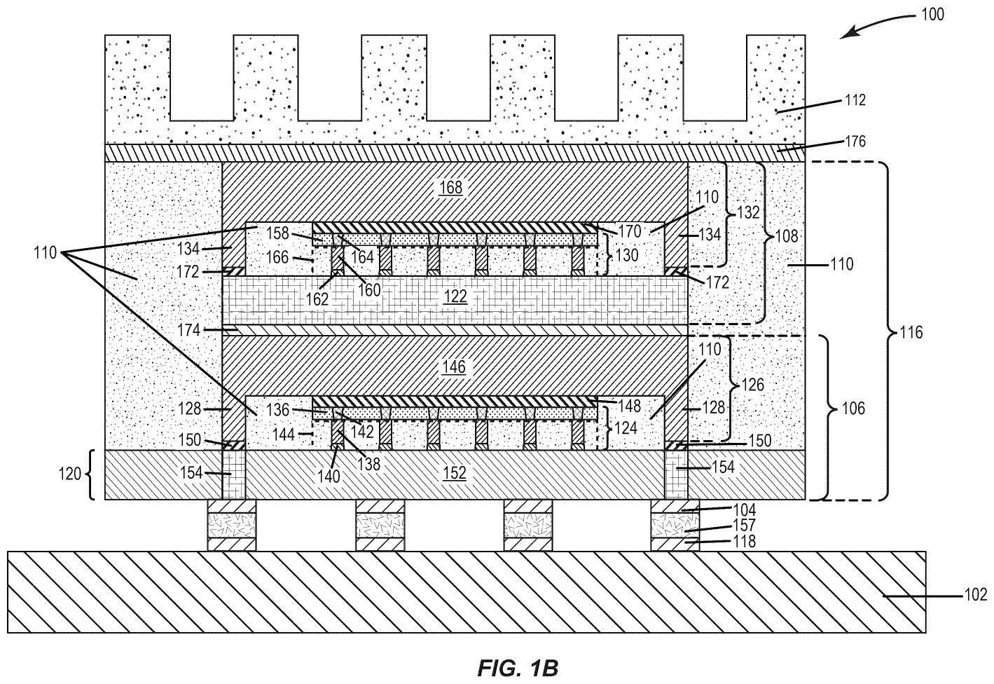

It will be understood that for clear illustrations, FIGS. 1A-22 may not be drawn to scale.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

For high-power radio frequency (RF) devices, such as gallium nitride (GaN)/gallium arsenide (GaAs) devices, bottom-side cooling through a package laminate substrate is limited, which may negatively impact electrical performance and device reliability. Top-side cooling for the high-power RF devices is imperative to establish as an additional thermal pathway to an ambient environment. Compared to wire-bonding dies, flip-chip assembly technology, besides its preferable solder interconnection to the package substrate (which helps in reducing the die size, reducing the overall size of the package, shorting the electrical path to the package laminate substrate, and reducing undesired inductance and capacitance), also provides the capability for the top-side cooling. A backside (i.e., the tallest portion) of one flip chip die is typically inactive, which allows the backside of the flip chip die to be connected to a high thermally conductive component above, so as to provide an upward heat dissipation path.

In addition, three-dimensional (3D) packaging techniques enable integration of multiple dies utilizing various substrates (e.g., laminate-based substrates, lead frame substrates, etc.) to achieve electronics densification in a small footprint. To enhance cooling efficiency for the multiple dies within the 3D stacking configuration, an oversized heat spreader is introduced to each of the dies (e.g., attached atop the die, more details are described below). The oversized heat spreaders can be vertically stacked to facilitate top and bottom side cooling, thereby enhancing thermal performance.

FIGS. 1A-1B illustrate an exemplary microelectronics package 100 with a stacked arrangement, which enables efficient thermal paths for both top-side cooling and bottom-side cooling, according to some embodiments of the present disclosure. For the purpose of this illustration, the microelectronics package 100 includes a carrier board 102, contact structures 104 (only one contact structure is labeled with a reference number for clarity), a first sub-package 106, a second sub-package 108, a mold compound 110, and a heat sink 112. Herein, the first sub-package 106 and the second sub-package 108 are vertically stacked and surrounded by the mold compound 110 to form a stacked assembly 116, which is coupled to the carrier board 102 via the electrical contacts 104. The heat sink 112 resides over the stacked assembly 116. In different applications, the microelectronics package 100 may include more sub-packages vertically stacked (i.e., the stacked assembly 116 is composed of more sub-packages).

The carrier board 102 may be a printed circuit board (PCB) that is made from FR4 or similar material and includes carrier connectors 118 (only one carrier connector is labeled with a reference number for clarity) on a top surface of the carrier board 102. The carrier connectors 118 are configured to accommodate the electrical contacts 104, respectively. The electrical contacts 104 are configured to electrically and thermally connect the stacked assembly 116 to the carrier board 102.

Within the stacked assembly 116, the first sub-package 106 and the second sub-package 108 include different types of substrates. For a non-limiting example, the first sub-package 106 includes a laminate-base substrate 120 (i.e., a first substrate), while the second sub-package 108 includes a lead frame substrate 122 (i.e., the second substrate 122). Besides the first substrate 120, the first sub-package 106 includes a first flip-chip die 124 and a first heat spreader 126 with an extended first periphery fence 128. Similarly, besides the second substrate 122, the second sub-package 108 includes a second flip-chip die 130 and a second heat spreader 132 with an extended second periphery fence 134.

In detail, the first flip-chip die 124 includes a first die body 136 and multiple first interconnects 138 extending outwardly from a bottom surface of the first die body 136 and coupled to a top surface of the first substrate 120. An active region (not shown) of the first flip-chip die 124 is located at a bottom portion of the first die body 136 and adjacent to the first interconnects 138. The first die body 136 may be formed from GaN with silicon carbide (SIC), GaAs with SiC, silicon, or any appropriate semiconductor material(s), and the first interconnects 138 may be copper pillars that are coupled to the first substrate 120 via first solder caps 140, respectively (only one first interconnect and one first solder cap of the first flip-chip die 124 are labeled with reference numbers for clarity). In some embodiments, the first flip-chip die 124 includes multiple first die vias 142 extending through the first die body 136 and coupled to corresponding first interconnects 138, respectively (only one first die via of the first flip-chip die 124 is labeled with a reference number for clarity). The first die vias 142 are configured to dissipate heat generated in the first die body 136 (e.g., heat generated by the active region of the first flip-chip die 124) towards a backside of the first flip-chip die 124, which enables top-side cooling of the first flip-chip die 124. In addition, the first flip-chip die 124 may be underfilled by a first underfilling material 144, such as an epoxy material, which encapsulates each first interconnect 138 and each first solder cap 140 and fills a cavity between the bottom surface of the first die body 136 and the top surface of the first substrate 120. The first underfilling material 144 is configured to ensure the integrity of the first solder caps 140 during a sintering process (more details are described below).

The first heat spreader 126 is an oversized heat spreader, which is at least 1.5 times larger than the first flip-chip die 124 in horizontal dimensions. The first heat spreader 126 includes a first lid 146 and the first periphery fence 128 extending outwardly from a periphery of a bottom surface of the first lid 146 and towards the top surface of the first substrate 120. The first heat spreader 126 may be formed of a material with a high thermal conductivity, such as SiC. The first flip-chip die 124 is thermally connected to and confined within the first heat spreader 126. In particular, the backside of the first flip-chip die 124 (i.e., a top surface of the first die body 136) is connected to the bottom surface of the first lid 146 through a first sintered layer 148. The first periphery fence 128 of the first heat spreader 126 may be composed of multiple discreate heat spreader legs with gaps in between (not shown) or may be a continuous heat spreader wall. The first periphery fence 128 of the first heat spreader 126 is connected to the top surface of the first substrate 120 through a first sintered component 150 and surrounds the first flip-chip die 124. If the first periphery fence 128 is composed of multiple discreate heat spreader legs, the first sintered component 150 includes corresponding discrete sections. If the first periphery fence 128 is a continuous heat spreader wall, the first sintered component 150 is also a continuous component, and the first flip-chip die 124 is encapsulated by the first heat spreader 126. The first sintered layer 148 and the first sintered components 150 may be formed of a sintering material with a high thermal conductivity (larger than 60 W/m·K, e.g., between 60 W/m·K and 75 W/m·K), such as sintering silver or sintering copper.

Herein, the heat generated in the first flip-chip die 124 (e.g., the heat generated by the active region of the first flip-chip die 124 located at the bottom portion of the first die body 136) can be dissipated upward through the first die vias 142, the first sintered layer 148, and the first lid 146 of the first heat spreader 126, and also be dissipated downward through the first die vias 142, the first sintered layer 148, the first lid 146, and the first periphery fence 128 towards the first substrate 120. Since the first heat spreader 126 is oversized and at least 1.5 times larger than the first flip-chip die 124, the heat generated in the first flip-chip die 124 can also be dissipated laterally by the first die vias 142, the first sintered layer 148, and the first lid 146, such that the concentrated heat flux in the first die body 136 can be relieved. Moreover, the first periphery fence 128 is configured to provide structural or mechanical support for the oversized first heat spreader 126 and may mitigate deformation risk of the first flip-chip die 124 and the substrate 120 during a molding process (more details are described below).

In some embodiments, the first substrate 120 is a laminate substrate and may be composed of organic materials and metal materials (used to form internal connections within the organic materials). For the purpose of this illustration, the first substrate 120 includes a substrate body 152 formed of one or more organic materials (e.g., FR4), and multiple thermal substrate vias 154 and internal electrical connections (not shown) within the substrate body 152. Each thermal substrate via 154 extends through the substrate body 152 and is thermally connected to the first periphery fence 128 via the first sintered component 150. If the first periphery fence 128 is composed of discreate heat spreader legs, each thermal substrate via 154 is thermally connected to a corresponding leg of the first periphery fence 128 via the first sintered component 150. The thermal substrate vias 154 may be formed of copper.

In addition, each thermal substrate via 154 of the first substrate 120 is also connected to a corresponding electrical contact 104 (other electrical contacts 104 are connected to the internal electrical connections within the substrate body 152, not shown for clarity and simplicity). As such, the heat generated by the first flip-chip die 124 can be further dissipated downward from the first periphery fence 128, through the thermal substrate via 154 of the first substrate 120, and towards the carrier board 102 through the corresponding contact structures 104. Note that, since the first interconnects 138 of the first flip-chip die 124 are not coupled to the thermal substrate via 154, and the substrate body 152 of the first substrate 120 does not have a high thermal conductivity, a combination of the first interconnects 138 and the first substrate 120 may not provide an efficient downward thermal path to the carrier board 102.

In different applications, the electrical contacts 104 may be implemented differently. As shown in FIG. 1A, each electrical contact 104 may include a substrate pad 155 and a reflowed solder ball 156, which is connected to a corresponding carrier connector 118. As such, the stacked assembly 116 is attached to the carrier board 102 using Ball Grid Array (BGA). In some cases, each electrical contact 104 may be a metal pad, which is connected to a corresponding carrier connector 118 via a solder paste 157. As such, the stacked assembly 116 is attached to the carrier board 102 using Land Grid Array (LGA), as shown in FIG. 1B.

The second sub-package 108 has a similar configuration to the first sub-package 106, except for a different type of substrate. In detail, the second flip-chip die 130 includes a second die body 158 and multiple second interconnects 160 extending outwardly from a bottom surface of the second die body 158 and coupled to a top surface of the second substrate 122. An active region (not shown) of the second flip-chip die 130 is located at a bottom portion of the second die body 158 and adjacent to the second interconnects 160. The second die body 158 may be formed from GaN with SiC or GaAs with SiC, and the second interconnects 160 may be copper pillars that are coupled to the second substrate 122 via second solder caps 162, respectively (only one second interconnect and one second solder cap of the second flip-chip die 130 are labeled with reference numbers for clarity). In some embodiments, the second flip-chip die 130 includes multiple second die vias 164 extending through the second die body 158 and coupled to corresponding second interconnects 160, respectively (only one second die via of the second flip-chip die 130 is labeled with a reference number for clarity). The second die vias 164 are configured to dissipate heat generated in the second die body 158 (e.g., heat generated in the active region of the second flip-chip die 130) towards a backside of the second flip-chip die 130, which enables top-side cooling of the second flip-chip die 130, and configured to dissipate heat generated in the second die body 158 towards the second interconnect 160, which enables down-side cooling of the second flip-chip die 130.

In addition, the second flip-chip die 130 may be underfilled by a second underfilling material 166, such as an epoxy material, which encapsulates each second interconnect 160 and each second solder cap 162, and fills gaps between the bottom surface of the second die body 158 and the top surface of the second substrate 122. The second underfilling material 166 is configured to ensure the integrity of the second solder caps 162 during a sintering process (more details are described below).

The second heat spreader 132 is an oversized heat spreader, which is at least 1.5 times larger than the second flip-chip die 130 in horizontal dimensions. The second heat spreader 132 includes a second lid 168 and the second periphery fence 134 extending outwardly from a periphery of a bottom surface of the second lid 168 and towards the top surface of the second substrate 122. The second heat spreader 132 may be formed of an insulating material with a high thermal conductivity, such as SiC. The second flip-chip die 130 is thermally connected to and confined within the second heat spreader 132. In particular, the backside of the second flip-chip die 130 (i.e., a top surface of the second die body 158) is connected to the bottom surface of the second lid 168 through a second sintered layer 170. The second periphery fence 134 of the second heat spreader 132 may be composed of multiple discreate heat spreader legs with gaps in between (not shown) or may be a continuous heat spreader wall. The second periphery fence 134 of the second heat spreader 132 is connected to the top surface of the second substrate 122 through a second sintered component 172 and surrounds the second flip-chip die 130. If the second periphery fence 134 is composed of discreate heat spreader legs, the second sintered component 172 includes corresponding discrete sections. If the second periphery fence 134 is a continuous heat spreader wall, the second sintered component 172 is also a continuous component, and the second flip-chip die 130 is encapsulated by the second heat spreader 132. The second sintered layer 170 and the second sintered components 172 may be formed of a sintering material with a high thermal conductivity (larger than 60 W/m·K, e.g., between 60 W/m·K and 75 W/m·K), such as sintering silver or sintering copper.

Herein, the heat generated in the second flip-chip die 130 (e.g., the heat generated by the active region of the second flip-chip die 130 located at the bottom portion of the second die body 158) can be dissipated upward through the second die vias 164, the second sintered layer 170, and the second lid 168 of the second heat spreader 132, and also be dissipated downward through the second die vias 164, and the second interconnects 160 towards the second substrate 122. In addition, the heat generated in the second flip-chip die 130 may also be dissipated from the second die vias 164, the second sintered layer 170, the second lid 168, and the second periphery fence 134 towards the second substrate 122. Since the second heat spreader 132 is oversized and at least 1.5 times larger than the second flip-chip die 130, the heat generated in the second flip-chip die 130 can also be dissipated laterally by the second die vias 164, the second sintered layer 170, and the second lid 168, such that the concentrated heat flux in the second die body 158 can be relieved. Moreover, the second periphery fence 134 is configured to provide structural or mechanical support for the oversized second heat spreader 132 and may mitigate deformation risk of the second flip-chip die 130 and the substrate 122 during a molding process (more details are described below). In some embodiments, the second substrate 122 is a lead frame substrate, which may be formed of a conducting material with a high thermal conductivity, such as copper, copper-alloy, or other appropriate metal/alloy.

The second sub-package 108 is vertically stacked with the first sub-package 106 via a package sintered layer 174. For the purpose of this illustration, a bottom surface of the second substrate 122 of the second sub-package 108 is attached to a top surface of the first heat spreader 126 of the first sub-package 106 (i.e., a top surface of the first lid 146 of the first heat spreader 126) via the package sintered layer 174. The package sintered layer 174 may be formed of a sintering material with a high thermal conductivity (larger than 60 W/m·K, e.g., between 60 W/m·K and 75 W/m·K), such as sintering silver or sintering copper. In addition, the heat sink 112 is attached to a top surface of the second heat spreader 132 of the second sub-package 108 (i.e., a top surface of the second lid 168 of the second heat spreader 132) via an adhesion layer 176, which is thermally conductive, such as a thermal gel, grease, or paste.

Accordingly, the heat generated by the second flip-chip die 130 within the second sub-package 108 can be dissipated further upward from the second lid 168 of the second heat spreader 132 to the heat sink 112, and further downward from the second substrate 122 (through the package sintered layer 174) to the first heat spreader 126, and even further downward to the carrier board 102 (through the first sintered component 150, the thermal substrate vias 154 within the first substrate 120, and the electrical contacts 104). The heat generated by the first flip-chip die 124 within the first sub-package 106 can be dissipated further upward from the first lid 146 of the first heat spreader 126 to the second heat spreader 132 (through the package sintered layer 174 and the second substrate 122), and even further upward to the heat sink 112. This stacked arrangement with the oversized heat spreaders 126/132, the thermal substrate vias 154 of the first substrate 120, and the thermal conductive second substrate 122 (e.g., the lead frame substrate) can efficiently conduct heat from the first and second flip-chip dies 124 and 130 (upward to the heat sink 112 and downward to the carrier board 102), resulting in a significant reduction in junction temperature within the microelectronics package 100. In some applications, the second flip-chip die 130 is a high-power RF die, while the first flip-chip die 124 is either a high-power die or a relatively low-power die.

The mold compound 110 is formed over the first substrate 120 of the first sub-package 106, underneath the heat sink 112, and around the first heat spreader 126 and the second sub-package 108. If the first periphery fence 128 of the first heat spreader 126 is composed of multiple discreate heat spreader legs, the mold compound 110 also fills a cavity between the first flip-chip die 124 and the first heat spreader 126 (in contact with and surrounding the first flip-chip die 124 and the first underfilling material 144). If the first periphery fence 128 is a continuous heat spreader wall, the first heat spreader 126 will provide an air cavity to the first flip-chip die 124 (not shown), and the mold compound 110 will not be in contact with the first flip-chip die 124. Similarly, if the second periphery fence 134 of the second heat spreader 132 is composed of multiple discreate heat spreader legs, the mold compound 110 will also fill a cavity between the second flip-chip die 130 and the second heat spreader 132 (in contact with and surrounding the second flip-chip die 130 and the second underfilling material 166). If the second periphery fence 134 is a continuous heat spreader wall, the second heat spreader 132 will provide an air cavity to the second flip-chip die 130 (not shown), and the mold compound 110 will not be in contact with the second flip-chip die 130.

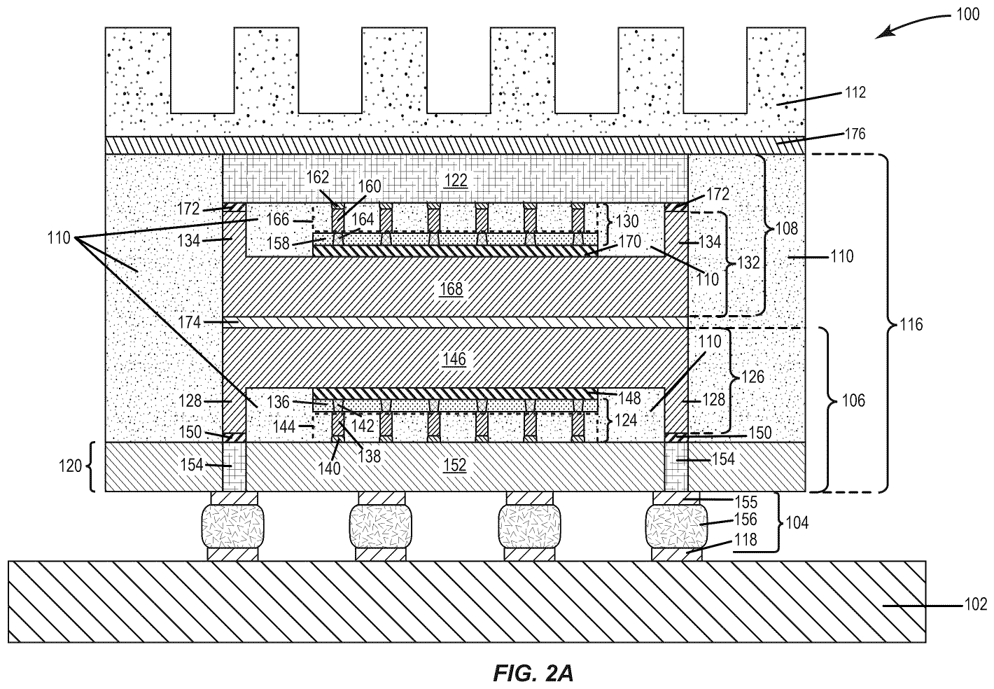

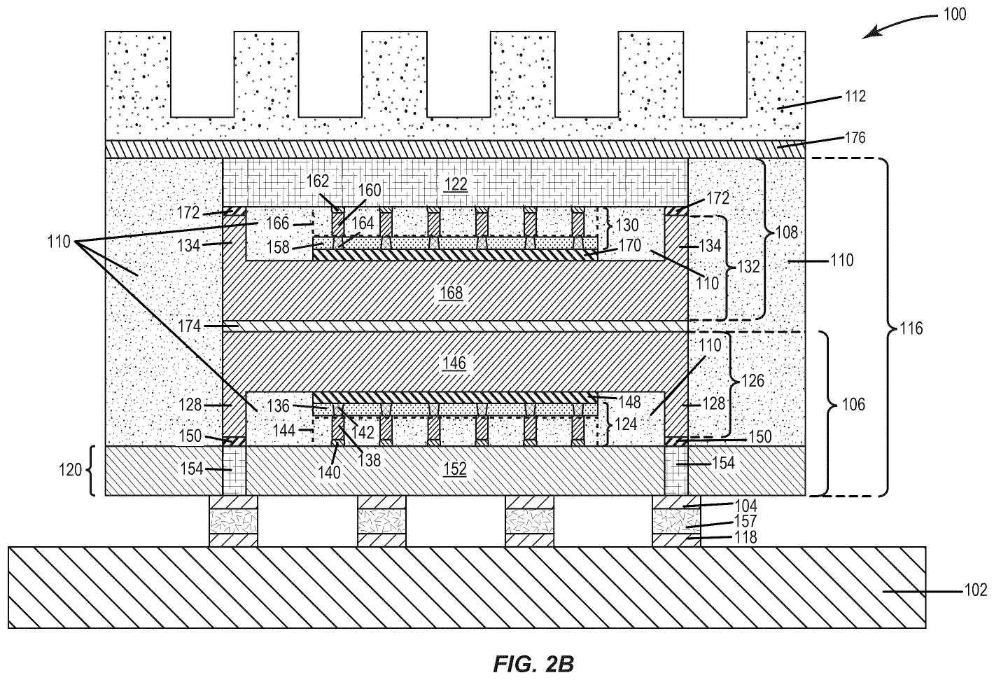

In some applications, the second sub-package 108 might be vertically stacked with the first sub-package 106 in a different configuration, as illustrated in FIGS. 2A and 2B. Herein, the stacked assembly 116 is still composed of the first sub-package 106, the second sub-package 108, and the mold compound 110. The heat sink 112 still resides over the stacked assembly 116, and the stacked assembly 116 is still connected to the carrier board 102 via the electrical contacts 104 (each electrical contact 104 may be a reflowed solder ball 156 as shown in FIG. 2A, or each electrical contact 104 may be a solder paste 157 as shown in FIG. 2B).

For the purpose of these illustrations, within the stacked assembly 116, the second sub-package 108 is flipped upside-down, such that a top surface and a bottom surface of each component within the second sub-package 108 is swapped. The second substrate 122 is located at the top portion of the second sub-package 108, while the second lid 168 of the second heat spreader 132 is located at the bottom portion of the second sub-package 108. In detail, the second flip-chip die 130 still includes the second die body 158 and the second interconnects 160 extending outwardly from a top surface of the second die body 158 and coupled to a bottom surface of the second substrate 122 via the second solder caps 162, respectively. The active region of the second flip-chip die 130 is located at a top portion of the second die body 158 and adjacent to the second interconnects 160. The second die vias 164 still extend through the second die body 158 and are coupled to the corresponding second interconnects 160, respectively. The second underfilling material 166 encapsulates each second interconnect 160 and each second solder cap 162, and fills gaps between the bottom surface of the second substrate 122 and the top surface of the second die body 158 of the second flip-chip die 130. The second heat spreader 132 still includes the second lid 168 and the second periphery fence 134 that extends outwardly from a periphery of a top surface of the second lid 168 and is connected to the bottom surface of the second substrate 122 through the second sintered component 172, so as to surround the second flip-chip die 130. A top surface of the second die body 158 of the second flip-chip die 130 is connected to the top surface of the second lid 168 of the second heat spreader 132 through the second sintered layer 170. In addition, a bottom surface of the second heat spreader 132 (i.e., a bottom surface of the second lid 168 of the second heat spreader 132) is attached to the top surface of the first heat spreader 126 of the first sub-package 106 (i.e., a top surface of the first lid 146 of the first heat spreader 126) via the package sintered layer 174. The heat sink 112 is attached to a top surface of the second substrate 122 of the second sub-package 108 via the adhesion layer 176. The mold compound 110 is still formed over the first substrate 120 of the first sub-package 106, underneath the heat sink 112, and around the first heat spreader 126 and the second sub-package 108. Optionally, the mold compound 110 may fill the cavities between the first flip-chip die 124 and the first heat spreader 126, and between the second flip-chip die 130 and the second heat spreader 132 (as described above).

The heat generated by the second flip-chip die 130 within the second sub-package 108 can be dissipated upward from the second die vias 164, the second interconnects 160, through the second substrate 122, and towards the heat sink 112, or from the second die vias 164, through the second sintered layer 170, the second lid 168, the second periphery fence 134, the second sintered component 172, and the second substrate 122, and towards the heat sink 112. In addition, the heat generated by the second flip-chip die 130 can be dissipated downward from the second die vias 164, through the second sintered layer 170, the second lid 168, the package sintered layer 174, the first heat spreader 126 (including the first lid 146 and the first periphery fence 128), the first sintered component 150, the thermal substrate vias 154 within the first substrate 120, and the electrical contacts 104, and towards the carrier board 102. The heat generated by the first flip-chip die 124 within the first sub-package 106 can also be dissipated downward (as described above) and upward from the first die vias 142, through the first sintered layer 148, the first lid 146 of the first heat spreader 126, the package sintered layer 174, the second heat spreader 132 (including the second lid 168 and the second periphery fence 134), the second sintered component 172, and the second substrate 122, and towards the heat sink 112.

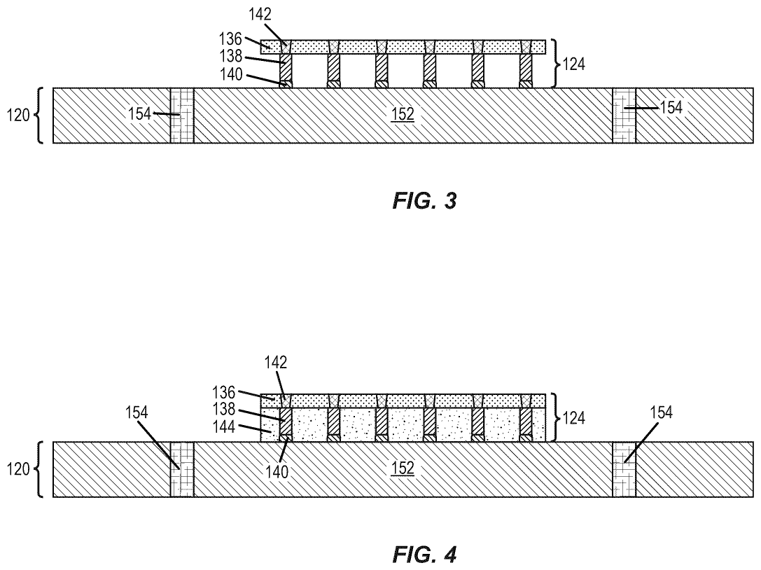

FIGS. 3-16B provide a process that illustrates exemplary steps to fabricate the microelectronics package 10 shown in FIGS. 1A and 1B according to some embodiments of the present disclosure. Although the exemplary steps are illustrated in a series, the exemplary steps are not necessarily order dependent. Some steps may be done in a different order than that presented. Further, processes within the scope of this disclosure may include fewer or more steps than those illustrated in FIGS. 3-16B.

With reference to FIGS. 3 through 6, the first sub-package 106 is formed according to one embodiment of the present disclosure. The first flip-chip die 124 is firstly attached to the top surface of the first substrate 120, as illustrated in FIG. 3. The first substrate 120 includes the substrate body 152, the multiple thermal substrate vias 154 extending through the substrate body 152, and internal electrical connections (not shown) within the substrate body 152. Herein, horizontal positions of the thermal substrate vias 154 within the substrate body 152 correspond to the shape of the first heat spreader 126 (i.e., positions of the first periphery fence 128 on the first lid 146), which is attached to the first flip-chip die 124 and the substrate body 152 in the following step. Each thermal substrate via 154 is exposed at the top surface and the bottom surface of the substrate body 152. The first flip-chip die 124 is not in contact with any of the thermal substrate vias 154 and is confined within a portion of the substrate body 152, which is surrounded by the multiple thermal substrate vias 154.

The first flip-chip die 124 may be a high-power RF die formed from GaN, GaAs, etc., or a relatively low-power die formed from silicon. The first flip-chip die 124 includes the first die body 136 and the first interconnects 138 extending outwardly from the bottom surface of the first die body 136 and is coupled to the top surface of the first substrate 120 (i.e., the top surface of the substrate body 152 of the first substrate 120) via the first solder caps 140. The active region (not shown) of the first flip-chip die 124 is located at the bottom portion of the first die body 136 and adjacent to the first interconnects 138. Herein, each first interconnect 138 is primarily configured to transmit electrical signals from the active region to the first substrate 120 without being thermally coupled to the thermal substrate vias 154. In some embodiments, the first flip-chip die 124 may also include the first die vias 142 that extend through the first die body 136 and are coupled to the corresponding first interconnects 138, respectively. As such, the heat generated in the first die body 136 can be dissipated to the backside of the first flip-chip die 124 through the first die vias 142.

Next, the first flip-chip die 124 is underfilled by the first underfilling material 144, as illustrated in FIG. 4. The first underfilling material 144 encapsulates each first interconnect 138 and each first solder cap 140, and fills gaps between the bottom surface of the first die body 136 of the first flip-chip die 124 and the top surface of the first substrate 120. A curing step may be followed to harden the first underfilling material 144 (not shown).

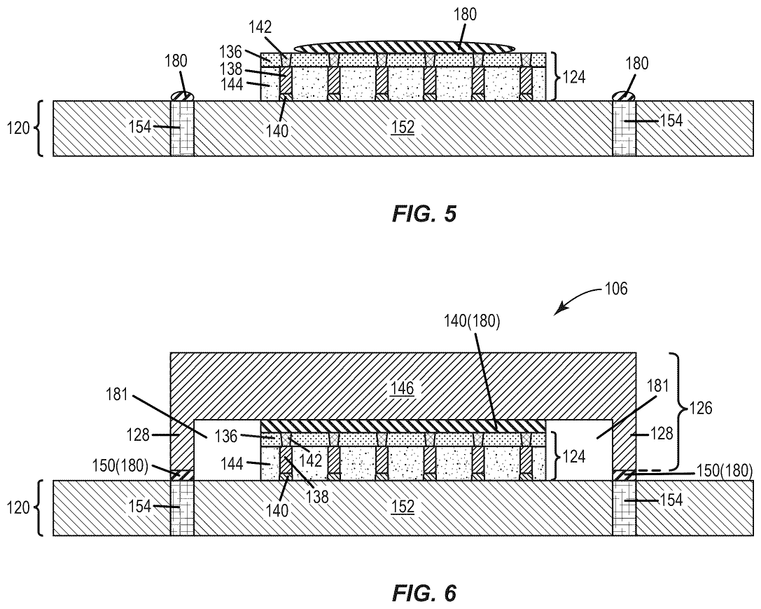

A first sintering material 180, which has a high thermal conductivity (larger than 60 W/m·K, e.g., between 60 W/m·K and 75 W/m·K), such as sintering silver or sintering copper, is then applied to the backside of the first flip-chip die 124 and an exposed top tip of each thermal substrate via 154 at the top surface of the substrate body 152, as illustrated in FIG. 5. The first sintering material 180 may be applied by a dispensing process. The applied amount of the first sintering material 180 is determined by the height of the first flip-chip die 124, a curing shrinkage rate of the first sintering material 180, and a height of the first periphery fence 128 of the first heat spreader 126, which is attached to the first flip-chip die 124 and the substrate body 152 in the following step. For a non-limiting example, if the first flip-chip die 124 is relatively short and the first periphery fence 128 of the first heat spreader 126 is relatively tall, the amount of the first sintering material 180 applied to the backside of the first flip-chip die 124 needs to be relatively large, and the amount of the first sintering material 180 applied to the exposed top tip of each thermal substrate via 154 needs to be relatively small, so as to ensure both reliable connections between the first heat spreader 126 and the first flip-chip die 124, and between the first heat spreader 126 and the first substrate 120 in the following step. In addition, if the curing shrinkage rate of the first sintering material 180 is relatively large, the applied amount of the first sintering material 180 needs to be relatively large to maintain a sufficient thickness after a curing step.

After the first sintering material 180 is applied, the first heat spreader 126 is placed over the first substrate 120 to cover the first flip-chip die 124 and to provide the first sub-package 106, as illustrated in FIG. 6. Herein, the first heat spreader 126 includes the first lid 146 and the first periphery fence 128 extending outwardly from the periphery of the bottom surface of the first lid 146. The first lid 146 resides over the first flip-chip die 124, such that the backside of the first flip-chip die 124 is coupled to the bottom surface of the first lid 146 through the first sintering material 180, and the first periphery fence 128 surrounds the first flip-chip die 124. In addition, the first periphery fence 128 of the first heat spreader 126 is aligned with and coupled to the thermal substrate vias 154 through the first sintering material 180. There is a first air cavity 181 provided horizontally between the first periphery fence 128 of the first heat spreader 126 and a combination the first flip-chip die 124 of the first underfilling material 144. If the first periphery fence 128 is composed of discreate heat spreader legs, each thermal substrate via 154 within the first substrate 120 is aligned with and coupled to a corresponding discreate heat spreader leg through the first sintering material 180, and the first air cavity 181 is not encapsulated. If the first periphery fence 128 is a continuous heat spreader wall, each thermal substrate via 154 within the first substrate 120 is aligned with a portion of the continuous heat spreader wall, and the first air cavity 181 is encapsulated.

Following the placement of the first heat spreader 126, the first sintering material 180 is cured (not shown). The first sintering material 180 between the backside of the first flip-chip die 124 and the bottom surface of the first lid 146 is converted to the first sintered layer 148, and the first sintering material 180 between the first periphery fence 128 of the first heat spreader 126 and the exposed top tips of the thermal substrate vias 154 is converted to the first sintered component 150. Since the applied amount of the first sintering material 180 is carefully determined, the first heat spreader 126 is reliably connected to the first flip-chip die 124 and the first substrate 120. If the first periphery fence 128 is composed of discreate heat spreader legs, the first sintered component 150 includes corresponding discrete sections. If the first periphery fence 128 is a continuous heat spreader wall, the first sintered component 150 is also a continuous component, and the first flip-chip die 124 is encapsulated by the first heat spreader 126. During the curing/sintering process, the first underfilling material 144 ensures the integrity of the first solder caps 140. Without the protection of the first underfilling material 144, the first solder caps 140 may be reflowed and cause electronic failure of the first flip-chip die 124.

The heat generated in the first die body 136 can be dissipated upward through the first die vias 142, the first sintered layer 148, and the first lid 146 of the first heat spreader 126, and also be dissipated downward through the first die vias 142, the first sintered layer 148, the first lid 146, the first periphery fence 128, and the thermal substrate vias 154 within the first substrate 120. Besides the thermal dissipation, the first periphery fence 128 is further configured to provide structural or mechanical support for the oversized first heat spreader 126 during the placement and curing process. Note that, since the first interconnects 138 of the first flip-chip die 124 are not coupled to the thermal substrate via 154, and the substrate body 152 of the first substrate 120 does not have a high thermal conductivity, a combination of the first interconnects 138 and the first substrate 120 may not provide an efficient downward thermal path.

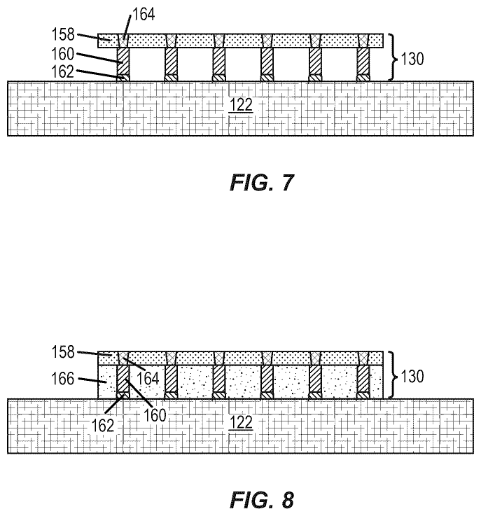

With reference to FIGS. 7 through 10, the second sub-package 108 is formed according to one embodiment of the present disclosure. The second flip-chip die 130 is firstly attached to the top surface of the second substrate 122, as illustrated in FIG. 7. In some embodiments, the second substrate 122 is a lead frame substrate, which may be formed of a conducting material with a high thermal conductivity, such as copper, copper-alloy, or other appropriate metal/alloy. Herein, the second flip-chip die 130 is located in a central portion of the top surface of the second substrate 122, such that a peripheral portion of the top surface of the second substrate 122 is exposed and not covered by the second flip-chip die 130.

The second flip-chip die 130 may be a high-power RF die, which is formed of GaN, GaAs, etc. The second flip-chip die 130 includes the second die body 158 and the second interconnects 160 extending outwardly from the bottom surface of the second die body 158 and coupled to the top surface of the second substrate 122 via the second solder caps 162. The active region (not shown) of the second flip-chip die 130 is located at the bottom portion of the second die body 158 and adjacent to the second interconnects 160. Herein, each second interconnect 160 is not only configured to transmit electrical signals from the active region to the second substrate 122, but also dissipate heat generated in the second die body 158 to the second substrate 122. In some embodiments, the second flip-chip die 130 may also include the second die vias 164 that extend through the second die body 158 and are coupled to the corresponding second interconnects 160, respectively. As such, the heat generated in the second die body 158 can be dissipated to the backside of the second flip-chip die 130 through the second die vias 164.

Next, the second flip-chip die 130 is underfilled by the second underfilling material 166, as illustrated in FIG. 8. The second underfilling material 166 encapsulates each second interconnect 160 and fills gaps between the bottom surface of the second die body 158 of the second flip-chip die 130 and the top surface of the second substrate 122. A curing step may be followed to harden the second underfilling material 166 (not shown).

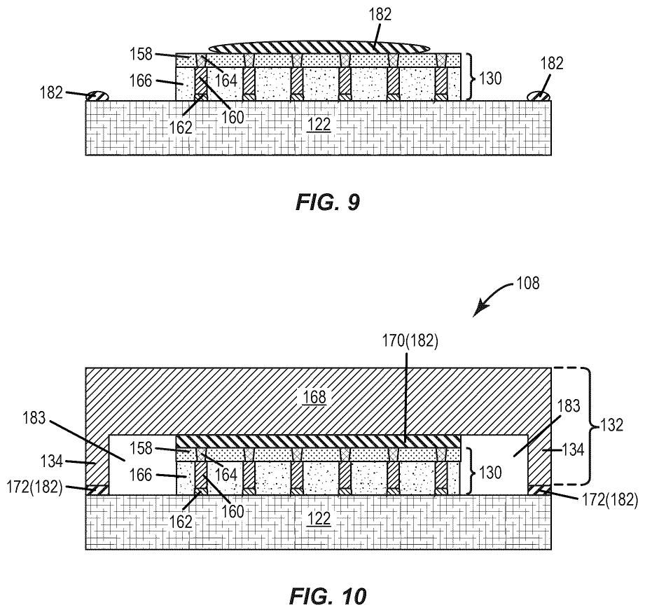

A second sintering material 182, which has a high thermal conductivity (larger than 60 W/m·K, e.g., between 60 W/m·K and 75 W/m·K), such as sintering silver or sintering copper, is then applied to the backside of the second flip-chip die 130 and the exposed peripheral portion of the top surface of the second substrate 122, as illustrated in FIG. 9. Herein, horizontal positions of the applied second sintering material 182 on the peripheral portion of the top surface of the second substrate 122 correspond to the shape of the second heat spreader 132 (i.e., positions of the second periphery fence 134 on the second lid 168), which is attached to the second flip-chip die 130 and the second substrate 122 in the following step. The second sintering material 182 may be applied by a dispensing process. The applied amount of the second sintering material 182 is determined by the height of the second flip-chip die 130, a curing shrinkage rate of the second sintering material 182, and a height of the second periphery fence 134 of the second heat spreader 132, which is attached to the second flip-chip die 130 and the second substrate 122 in the following step. For a non-limiting example, if the second flip-chip die 130 is relatively short and the second periphery fence 134 of the second heat spreader 132 is relatively tall, the amount of the second sintering material 182 applied to the backside of the second flip-chip die 130 needs to be relatively large, and the amount of the second sintering material 182 applied to the exposed peripheral portion of the top surface of the second substrate 122 needs to be relatively small, so as to ensure both reliable connections between the second heat spreader 132 and the second flip-chip die 130, and between the second heat spreader 132 and the second substrate 122 in the following step. In addition, if the curing shrinkage rate of the second sintering material 182 is relatively large, the applied amount of the second sintering material 182 needs to be relatively large to maintain a sufficient thickness after a curing step.

After the second sintering material 182 is applied, the second heat spreader 132 is placed over the second substrate 122 to cover the second flip-chip die 130 and to provide the second sub-package 108, as illustrated in FIG. 10. Herein, the second heat spreader 132 includes the second lid 168 and the second periphery fence 134 extending outwardly from the periphery of the bottom surface of the second lid 168. The second lid 168 resides over the second flip-chip die 130, such that the backside of the second flip-chip die 130 is coupled to the bottom surface of the second lid 168 through the second sintering material 182, and the second periphery fence 134 surrounds the second flip-chip die 130. In addition, the second periphery fence 134 of the second heat spreader 132 is attached to the top surface of the second substrate 122 via the second sintering material 182. There is a second air cavity 183 provided horizontally between the second periphery fence 134 of the second heat spreader 132 and a combination of the second flip-chip die 130 and the second underfilling material 166. If the second periphery fence 132 is composed of discreate heat spreader legs, the second air cavity 183 is not encapsulated. If the second periphery fence 132 is a continuous heat spreader wall, the second air cavity 183 is encapsulated.

Following the placement of the second heat spreader 132, the second sintering material 182 is cured (not shown). The second sintering material 182 between the backside of the second flip-chip die 130 and the bottom surface of the second lid 168 is converted to the second sintered layer 172, and the second sintering material 182 between the second periphery fence 134 of the second heat spreader 132 and the top surface of the second substrate 122 is converted to the second sintered component 172. Since the applied amount of the second sintering material 182 is carefully determined, the second heat spreader 132 is reliably connected to the second flip-chip die 130 and the second substrate 122. If the second periphery fence 134 is composed of discreate heat spreader legs, the second sintered component 172 includes corresponding discrete sections. If the second periphery fence 134 is a continuous heat spreader wall, the second sintered component 172 is also a continuous component, and the second flip-chip die 130 is encapsulated by the second heat spreader 132. During the curing/sintering process, the second underfilling material 166 ensures the integrity of the second solder caps 162. Without the protection of the second underfilling material 166, the second solder caps 162 may be reflowed and cause electronic failure of the second flip-chip die 130.

The heat generated in the second flip-chip die 130 (e.g., the heat generated by the active region of the second flip-chip die 130 located at the bottom portion of the second die body 158) can be dissipated upward through the second die vias 164, the second sintered layer 170, and the second lid 168 of the second heat spreader 132, and also be dissipated downward through the second die vias 164, the second interconnects 160, and the second substrate 122 or through the second die vias 164, the second sintered layer 170, the second lid 168, the second periphery fence 134, and the second substrate 122. Besides the thermal dissipation, the second periphery fence 134 is further configured to provide structural or mechanical support for the oversized second heat spreader 132 during the placement and curing process.

Herein, since the first sub-package 106 and the second sub-package 108 are formed separately, the first sub-package 106 and the second sub-package 108 can be formed simultaneously or in a different order. Within the first sub-package 106, the horizontal size of the first heat spreader 126 is smaller than the horizontal size of the first substance 120, and within the second sub-package 108, the horizontal size of the second heat spreader 132 is no larger than the horizontal size of the second substance 120. In addition, a footprint of the second sub-package 108 is typically no larger than a footprint of the first sub-package 106.

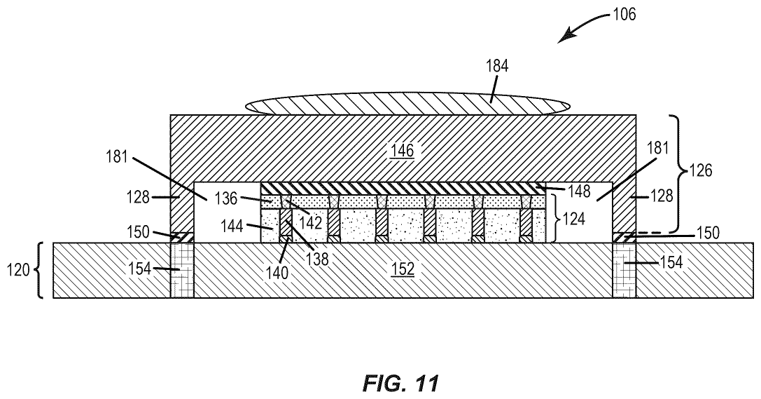

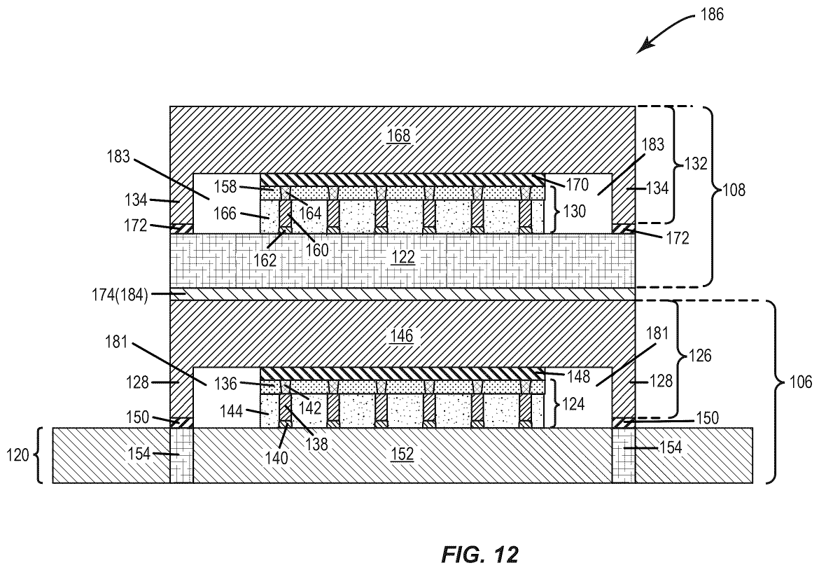

Once the first sub-package 106 and the second sub-package 108 are completed, processing steps are performed to form the stacked assembly 116. A third sintering material 184, which has a high thermal conductivity (larger than 60 W/m·K, e.g., between 60 W/m·K and 75 W/m·K), such as sintering silver or sintering copper, is applied to the top surface of the first heat spreader 126 (i.e., the top surface of the first lid 146), as illustrated in FIG. 11. The third sintering material 184 may be applied by a dispensing process. Next, the second sub-package 108 is placed over the first sub-package 106 to provide a package-on-package (POP) structure 186, as illustrated in FIG. 12. Herein, the bottom surface of the second substrate 122 is attached to the top surface of the first heat spreader 126 via the third sintering material 184. As such, the top surface of the second heat spreader 132 (i.e., the top surface of the second lid 168 of the second heat spreader 132) is exposed and is a top surface of the POP structure 186. In some embodiments, the horizontal size of the first heat spreader 126 may be substantially the same as the horizontal size of the second substrate 122, and the horizontal size of the second heat spreader 132 might be substantially the same as or smaller than the horizontal size of the second substrate 122 (not shown).

Following the placement of the second sub-package 108 over the first sub-package 106, the third sintering material 184 between the top surface of the first sub-package 106 (i.e., the top surface of the first lid 146 of the first heat spreader 126) and the bottom surface of the second sub-package 108 (i.e., the bottom surface of the second substrate 122) is cured and converted to the package sintered layer 174. During this curing/sintering process, the first underfilling material 144 and the second underfilling material 166 protect the first solder caps 140 and the second solder caps 162, respectively.

The second sub-package 108 is thermally connected with the first sub-package 106. Accordingly, the heat generated by the second flip-chip die 130 within the second sub-package 108 can be dissipated further downward from the second substrate 122 (through the package sintered layer 174) to the first heat spreader 126, and the heat generated by the first flip-chip die 124 within the first sub-package 106 can be dissipated further upward from the first lid 146 of the first heat spreader 126 to the second heat spreader 132 through the package sintered layer 174 and the second substrate 122. In addition, since the first heat spreader 126, the second heat spreader 132, and the second substrate 122 are oversized in the horizontal dimensions compared to the first flip-chip die 124 and the second flip-chip die 130 (e.g., at least 1.5 times larger than the first flip-chip die 124/the second flip-chip die 130), the heat generated in the first flip-chip die 124 and the second flip-chip die 130 can also be dissipated laterally in the first heat spreader 126, the second heat spreader 132, and the second substrate 122, such that the heat flux concentrated in the first die body 136 and in the second die body 158 can be relieved.

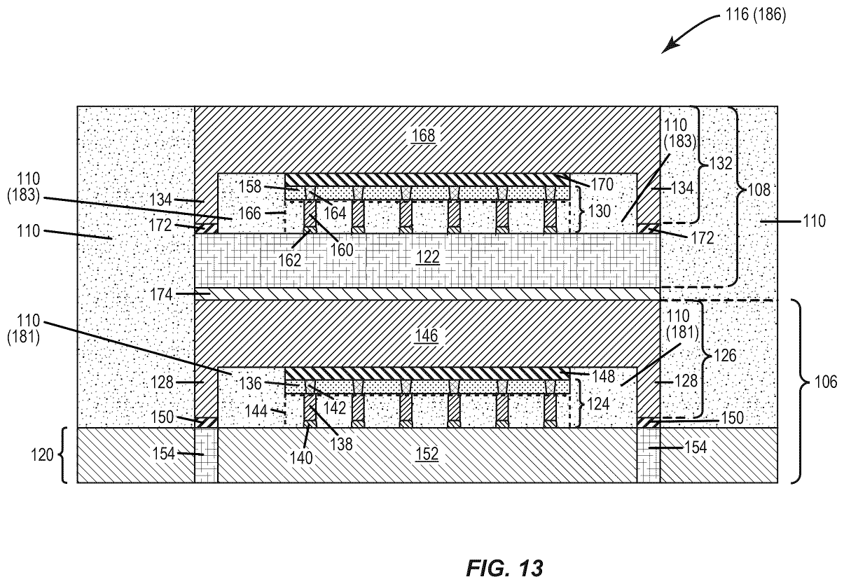

After the second sub-package 108 is vertically stacked with the first sub-package 106, the mold compound 110 is applied to the POP structure 186 to complete the stacked assembly 116, as illustrated in FIG. 13. Herein, the mold compound 110 is formed over the first substrate 120 of the first sub-package 106 and around the first heat spreader 126 and the second sub-package 108. The top surface of the POP structure 186 (i.e., the top surface of the second lid 168 of the second heat spreader 132) is exposed and is not covered by the mold compound 110. A top surface of the stacked assembly 116 is a combination of the top surface of the second lid 168 of the second heat spreader 132 and a top surface of the mold compound 110. The mold compound 110 may be applied by film-assisted molding, and the like.

If the first periphery fence 128 of the first heat spreader 126 is composed of multiple discreate heat spreader legs, the mold compound 110 will fill the first air cavity 181 and be in contact with the first flip-chip die 124 and the first underfilling material 144. If the first periphery fence 128 is a continuous heat spreader wall, the mold compound 110 will not fill the first air cavity 181 and will not be in contact with the first flip-chip die 124 (not shown). Similarly, if the second periphery fence 134 of the second heat spreader 132 is composed of multiple discreate heat spreader legs, the mold compound 110 will fill the second air cavity 183 and be in contact with the second flip-chip die 130 and the second underfilling material 166. If the second periphery fence 134 is a continuous heat spreader wall, the mold compound 110 will not fill the second air cavity 183 and will not be in contact with the second flip-chip die 130 (not shown).

The first underfilling material 144, the second underfilling material 166, and the mold compound 110 may be formed from a same material, such as epoxy. During this molding step, the first underfilling material 144 may provide mechanical support to the first die body 136, the first interconnect 138, and the first solder caps 140, while the second underfilling material 166 may provide mechanical support to the second die body 158, the second interconnect 160, and the second solder caps 164, so as to mitigate deformation risk of the first flip-chip die 124 and the second flip-chip die 130. In addition, the first periphery fence 128 of the first heat spreader 126 and the second periphery fence 134 of the second heat spreader 132 may provide structural/mechanical support for the oversized first heat spreader 126 and the oversized second periphery fence 132, respectively, and may also mitigate deformation risk of the first flip-chip die 124, the first substrate 120, the second flip-chip die 130, and the second substate 122. A curing step may be followed to harden the mold compound 110 (not shown).

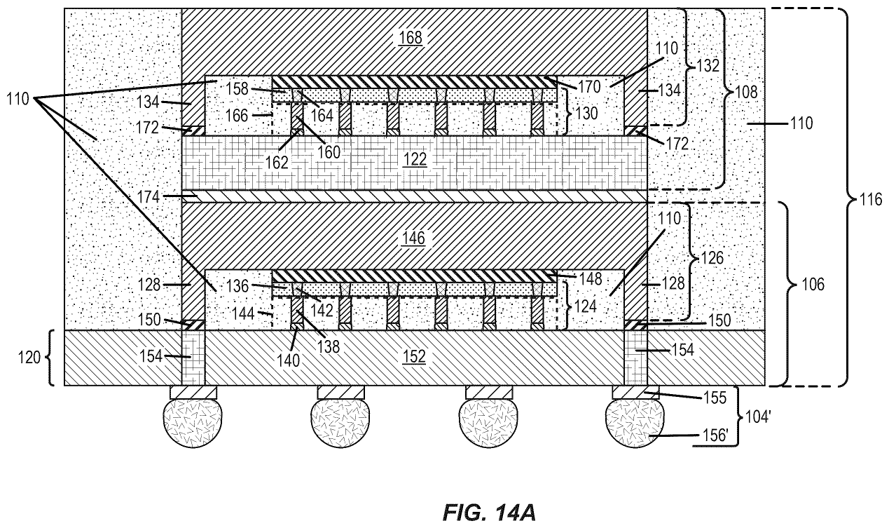

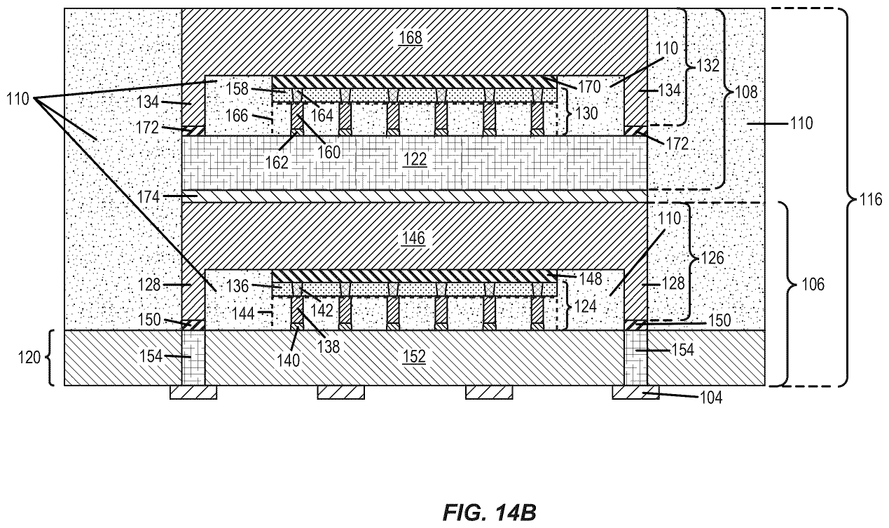

In some embodiments, the BGA technology is used for further attachment of the stacked assembly 116. As shown in FIG. 14A, initial electrical contacts 104′, each of which includes one substrate pad 155 and an initial solder ball 156′, are formed at a bottom surface of the stacked assembly 116 (i.e., the bottom surface of the first substrate 120 of the first sub-package 106). Each thermal substrate via 154 within the first substrate 120 is connected to a corresponding initial electrical contact 104′ (other initial electrical contacts 104′ are connected to the internal electrical connections within the first substrate 120, not shown for clarity and simplicity). In some embodiments, the LGA technology is used for further attachment of the stacked assembly 116. As shown in FIG. 14B, the electrical contacts 104, each of which is one plated metal pad, are formed at the bottom surface of the stacked assembly 116. Each thermal substrate via 154 within the first substrate 120 is connected to a corresponding electrical contact 104 (other electrical contacts 104 are connected to the internal electrical connections within the first substrate 120, not shown for clarity and simplicity).

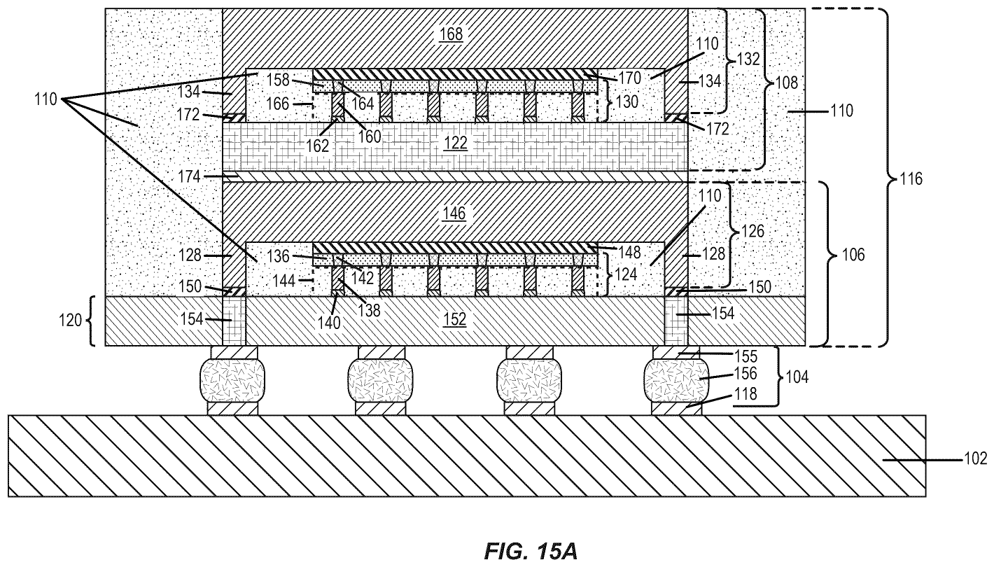

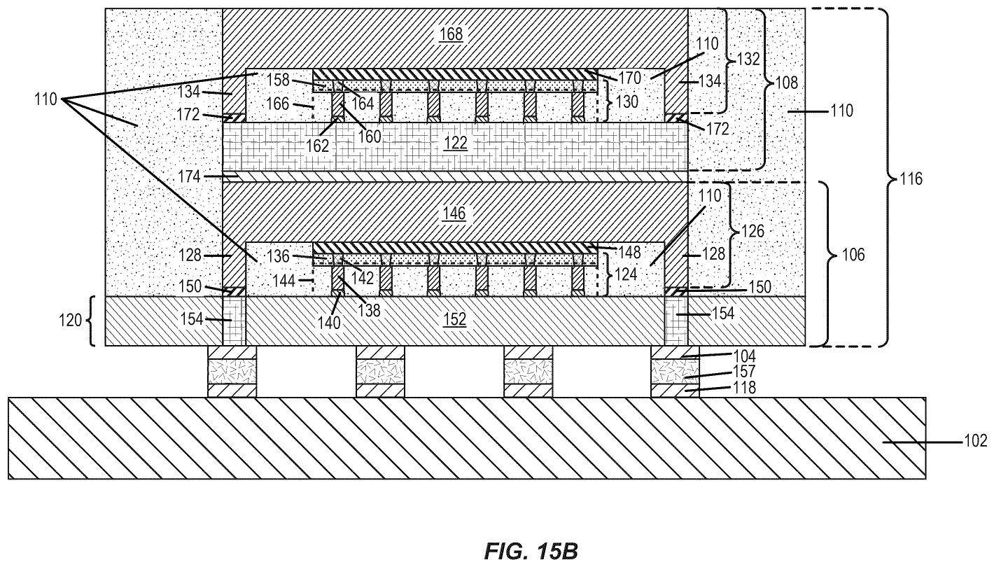

Next, the stacked assembly 116 is attached to the carrier board 102, as illustrated in FIGS. 15A and 15B. For the case of the BGA technology, each initial solder ball 156′ reflows and is in contact with a corresponding carrier connector 118 on the top surface of the carrier board 102 (FIG. 15A). Each initial solder ball 156′ is converted to the reflowed solder ball 156, and each initial electrical contact 104′ is converted to the electrical contact 104. For the case of the LGA technology, each electrical contact 104 (each plated metal pad) is connected to a corresponding carrier connector 118 via the solder paste 157 (FIG. 15B). Regardless of whether the BGA or LGA is used, the heat generated from the first flip-chip die 124 and/or the second flip-chip die 130 within the stacked assembly 116 can be further dissipated downwards to the carrier board 102 through the thermal substrate vias 154 of the first substrate 120 and the electrical contacts 104.

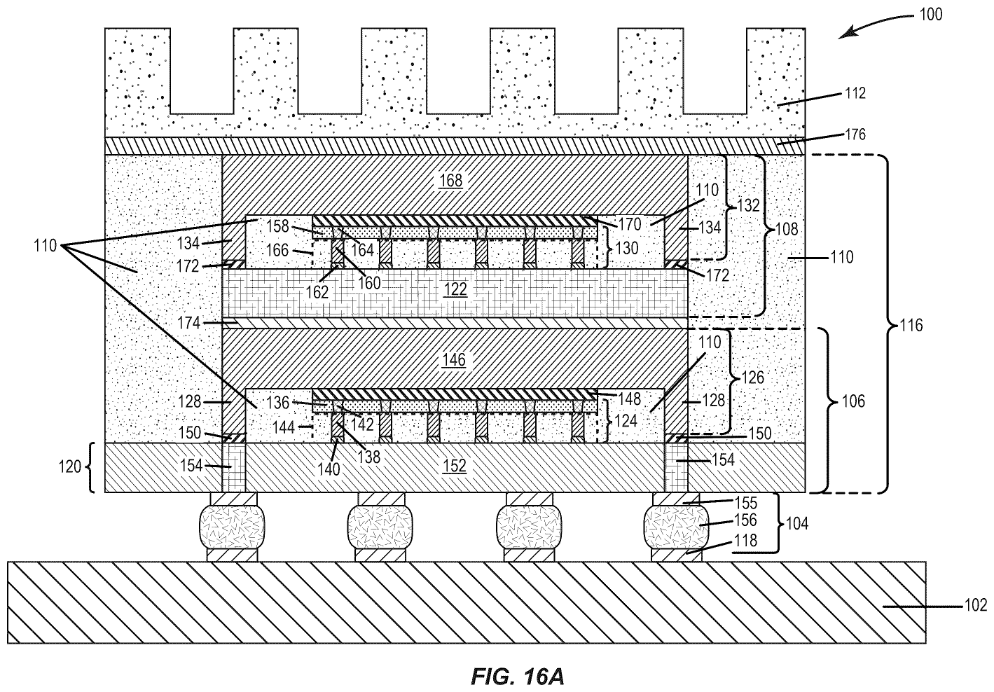

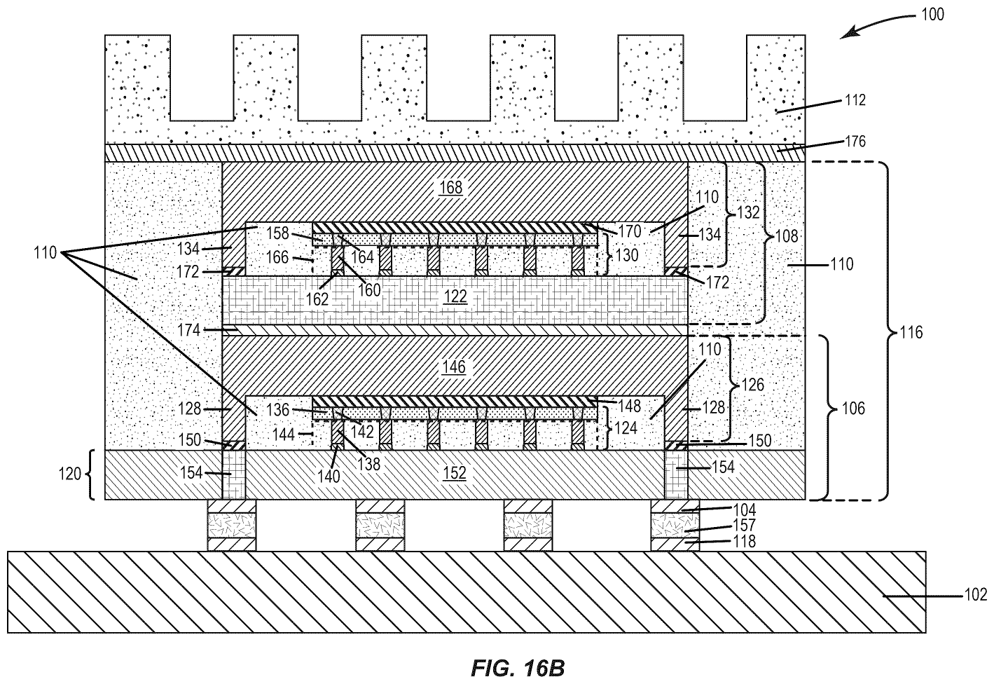

Lastly, the heat sink 112 may be attached to the top surface of the stacked assembly 116 via the adhesion layer 176, as illustrated in FIGS. 16A and 16B. Herein, the top surface of the second lid 168 of the second heat spreader 132 is thermally connected to the heat sink 112 through the adhesion layer 176. As such, the heat generated from the second flip-chip die 130 and/or the first flip-chip die 124 within the stacked assembly 116 can be further dissipated upwards to the heat sink 112.

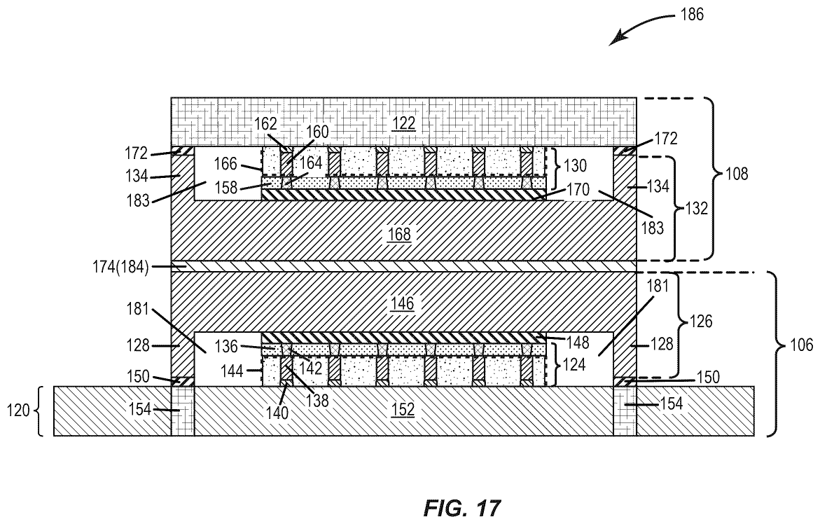

FIGS. 17-21B provide an alternative process that illustrates steps to fabricate the microelectronics packages shown in FIGS. 2A and 2B according to some embodiments of the present disclosure. Although the exemplary steps are illustrated in a series, the exemplary steps are not necessarily order dependent. Some steps may be done in a different order than that presented. Further, processes within the scope of this disclosure may include fewer or more steps than those illustrated in FIGS. 17-21B.

After the first sub-package 106 and the second sub-package 108 are formed (FIGS. 6 and 10), and the third sintering material 184 is applied to the top surface of the first heat spreader 126 (FIG. 11), the second sub-package 108 is flipped upside down and placed over the first sub-package 106 to provide the POP structure 186, as illustrated in FIG. 17. As such, a top surface and a bottom surface of each component within the second sub-package 108 is swapped. The second substrate 122 is located at the top portion of the second sub-package 108, while the second lid 168 of the second heat spreader 132 is located at the bottom portion of the second sub-package 108. Herein, the bottom surface of the second heat spreader 132 (i.e., the bottom surface of the second lid 168 of the second heat spreader 132) is attached to the top surface of the first heat spreader 126 of the first sub-package 106 (i.e., the top surface of the first lid 146 of the first heat spreader 126) via the third sintering material 184. As such, the top surface of the second substrate 122 is exposed and is a top surface of the POP structure 186. In some embodiments, the horizontal size of the first heat spreader 126 may be substantially the same as the horizontal size of the second heat spreader 132, and the horizontal size of the second substrate 122 may be substantially the same as or larger than the horizontal size of the second heat spreader 132 (not shown).

Following the placement of the second sub-package 108 over the first sub-package 106, the third sintering material 184 between the top surface of the first sub-package 106 (i.e., the top surface of the first lid 146 of the first heat spreader 126) and the bottom surface of the second sub-package 108 (i.e., the bottom surface of the second lid 168 of the second heat spreader 132) is cured and is converted to the package sintered layer 174. The second sub-package 108 is thermally connected with the first sub-package 106. Accordingly, the heat generated by the second flip-chip die 130 within the second sub-package 108 can be dissipated further downward from the second heat spreader 132 (through the package sintered layer 174) to the first heat spreader 126, and the heat generated by the first flip-chip die 124 within the first sub-package 106 can be dissipated further upward from the first heat spreader 126 to the second substrate 122 through the package sintered layer 174 and the second heat spreader 132. In addition, since the first heat spreader 126 and the second heat spreader 132 are oversized in the horizontal dimensions compared to the first flip-chip die 124 and the second flip-chip die 130 (e.g., at least 1.5 times larger than the first flip-chip die 124/the second flip-chip die 130), the heat generated in the first flip-chip die 124 and the second flip-chip die 130 can also be dissipated laterally in the first heat spreader 126 and the second heat spreader 132, such that the heat flux concentrated in the first die body 136 and in the second die body 158 can be relieved.

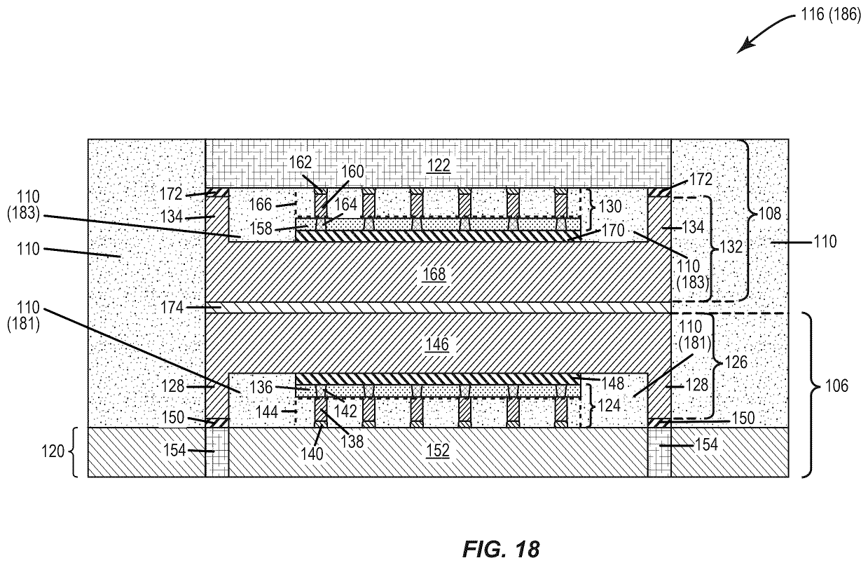

After the second sub-package 108 is vertically stacked with the first sub-package 106, the mold compound 110 is applied to the POP structure 186 to complete the stacked assembly 116, as illustrated in FIG. 18. Herein, the mold compound 110 is formed over the first substrate 120 of the first sub-package 106 and around the first heat spreader 126 and the second sub-package 108. The top surface of the PoP structure 186 (i.e., the top surface of the second substrate 122) is exposed and is not covered by the mold compound 110. As such, the top surface of the stacked assembly 116 is a combination of the top surface of the second substrate 122 and the top surface of the mold compound 110. The mold compound 110 may be applied by film-assisted molding, and the like.

If the first periphery fence 128 of the first heat spreader 126 is composed of multiple discreate heat spreader legs, the mold compound 110 will fill the first air cavity 181 and be in contact with the first flip-chip die 124 and the first underfilling material 144. If the first periphery fence 128 is a continuous heat spreader wall, the mold compound 110 will not fill the first air cavity 181 and will not be in contact with the first flip-chip die 124 (not shown). Similarly, if the second periphery fence 134 of the second heat spreader 132 is composed of multiple discreate heat spreader legs, the mold compound 110 will fill the second air cavity 183 and be in contact with the second flip-chip die 130 and the second underfilling material 166. If the second periphery fence 134 is a continuous heat spreader wall, the mold compound 110 will not fill the second air cavity 183 and will not be in contact with the second flip-chip die 130 (not shown).

During this molding step, the first underfilling material 144 may provide mechanical support to the first die body 136, the first interconnects 138, and the first solder caps 140, so as to mitigate deformation risk of the first flip-chip die 124. The first periphery fence 128 of the first heat spreader 126 may provide structural/mechanical support for the oversized first heat spreader 126 and may also mitigate deformation risk of the first flip-chip die 124 and the first substrate 120. In addition, the second underfilling material 166 may provide mechanical support to the second die body 158, the second interconnects 160, and the second solder caps 162, so as to mitigate deformation risk of the second flip-chip die 130. The second periphery fence 134 of the second heat spreader 132 may provide structural/mechanical support for the second substrate 122 and may also mitigate deformation risk of the second flip-chip die 130 and the second substrate 122. A curing step may be followed to harden the mold compound 110 (not shown).

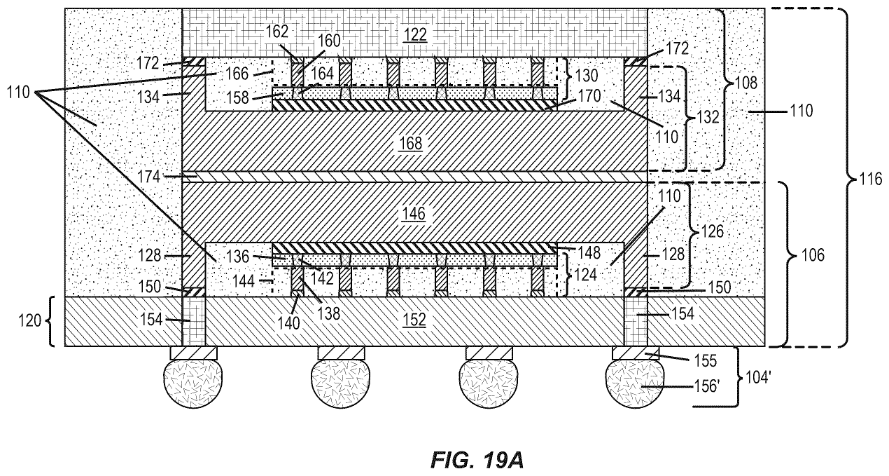

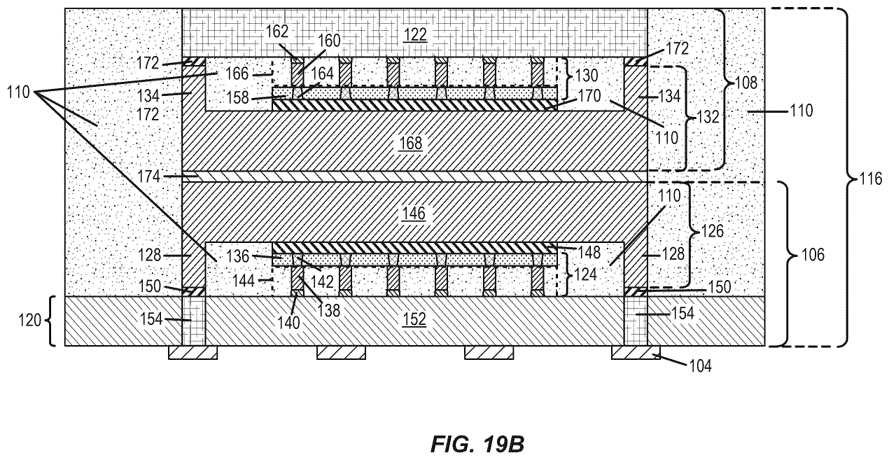

In some embodiments, the BGA technology is used for further attachment of the stacked assembly 116. As shown in FIG. 19A, the initial electrical contacts 104′, each of which includes one substrate pad 155 and one initial solder ball 156′, are formed at the bottom surface of the stacked assembly 116 (i.e., the bottom surface of the first substrate 120 of the first sub-package 106). Each thermal substrate via 154 within the first substrate 120 is connected to the corresponding initial electrical contact 104′ (other initial electrical contacts 104′ are connected to the internal electrical connections within the first substrate 120, not shown for clarity and simplicity). In some embodiments, the LGA technology is used for further attachment of the stacked assembly 116. As shown in FIG. 19B, the electrical contacts 104, each of which is one plated metal pad, are formed at the bottom surface of the stacked assembly 116. Each thermal substrate via 154 within the first substrate 120 is connected to a corresponding electrical contact 104 (other electrical contacts 104 are connected to the internal electrical connections within the first substrate 120, not shown for clarity and simplicity).

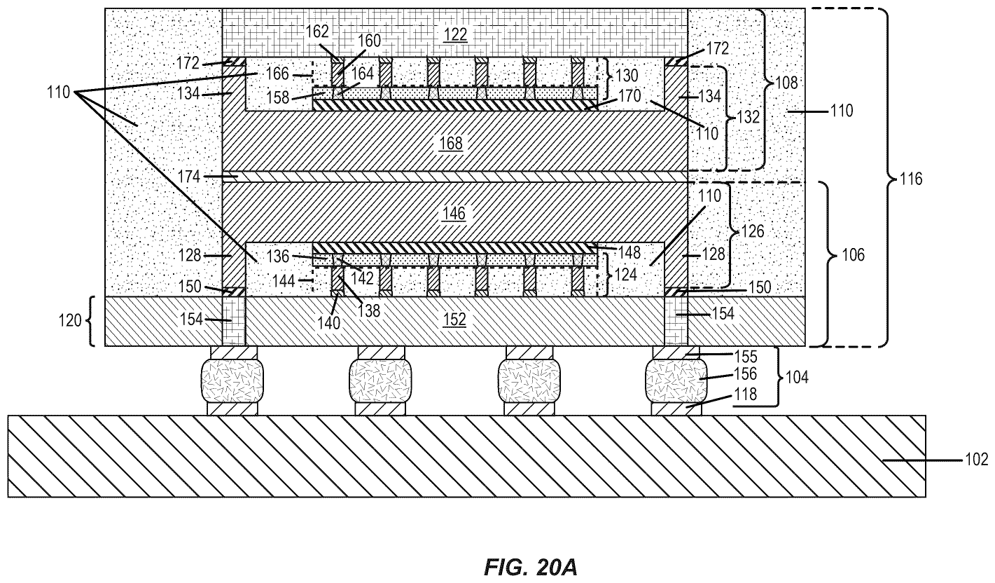

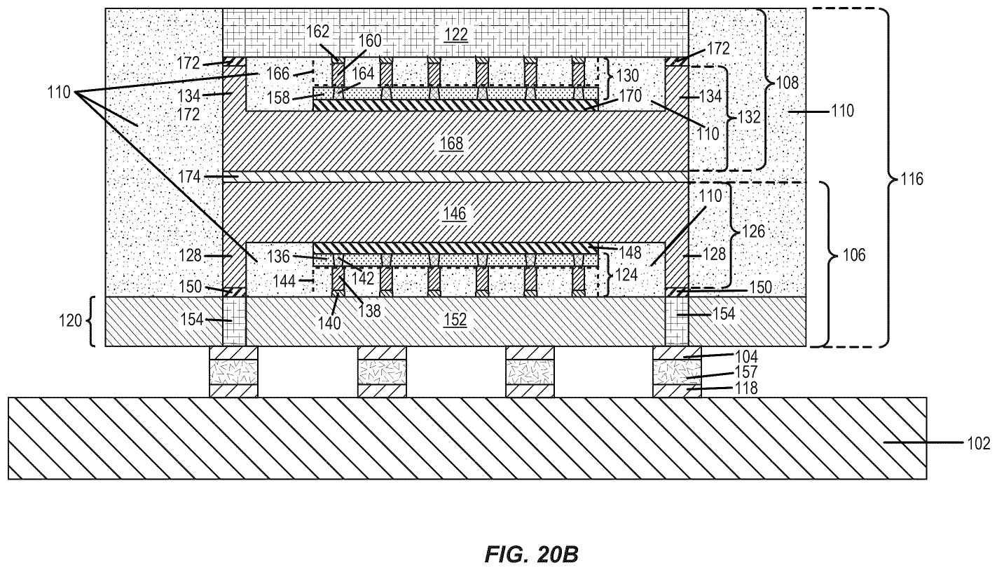

Next, the stacked assembly 116 is attached to the carrier board 102, as illustrated in FIGS. 20A and 20B. For the case of the BGA technology, each initial solder ball 156′ reflows and is in contact with a corresponding carrier connector 118 on the top surface of the carrier board 102 (FIG. 20A). Each initial solder ball 156′ is converted to the reflowed solder ball 156, and each initial electrical contact 104′ is converted to the electrical contact 104. For the case of the LGA technology, each electrical contact 104 (each plated metal pad) is connected to a corresponding carrier connector 118 via the solder paste 157 (FIG. 20B). Regardless of whether the BGA or LGA is used, the heat generated from the first flip-chip die 124 and/or the second flip-chip die 130 within the stacked assembly 116 can be further dissipated downwards to the carrier board 102 through the thermal substrate vias 154 of the first substrate 120 and the electrical contacts 104.

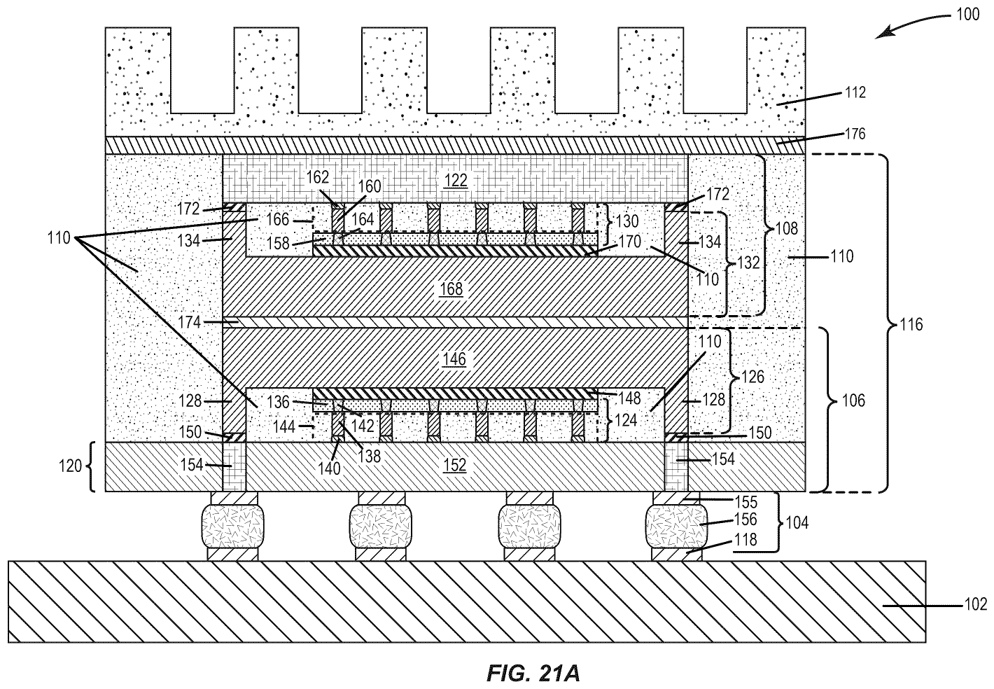

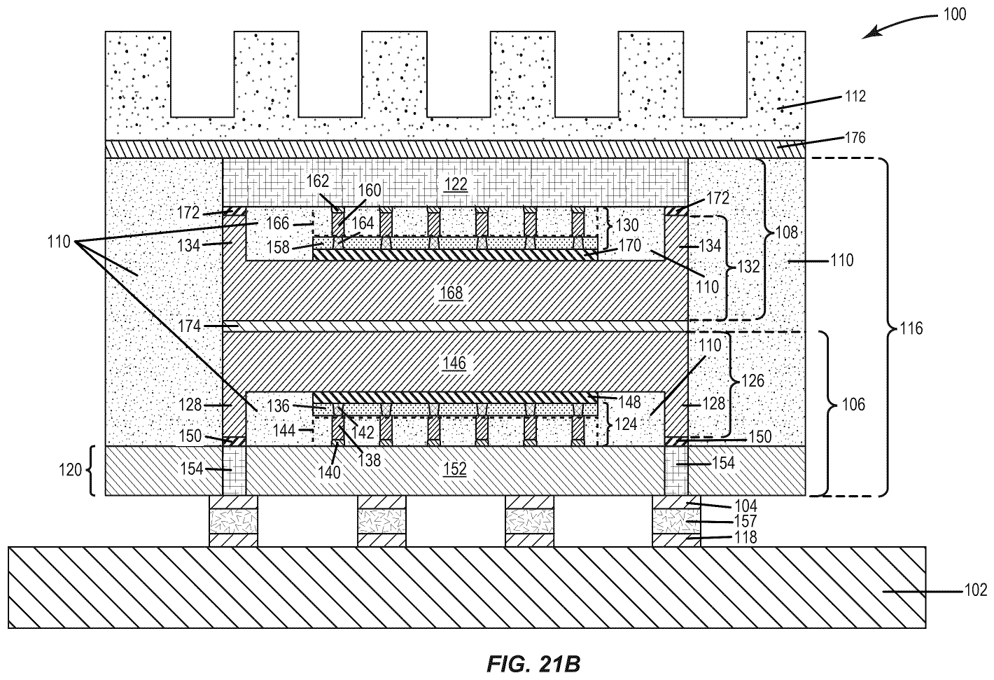

Lastly, the heat sink 112 may be attached to the top surface of the stacked assembly 116 via the adhesion layer 176, as illustrated in FIGS. 21A and 21B. Herein, the top surface of the second substrate 122 is thermally connected to the heat sink 112 through the adhesion layer 176. As such, the heat generated from the second flip-chip die 130 and/or the first flip-chip die 124 within the stacked assembly 116 can be further dissipated upwards to the heat sink 112.

The systems and methods for efficient heat dissipation of a stacked microelectronic package, according to aspects disclosed herein, may be provided in or integrated into any high-power processor-based electronics. Examples, without limitation, include a base station, a military application device, a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

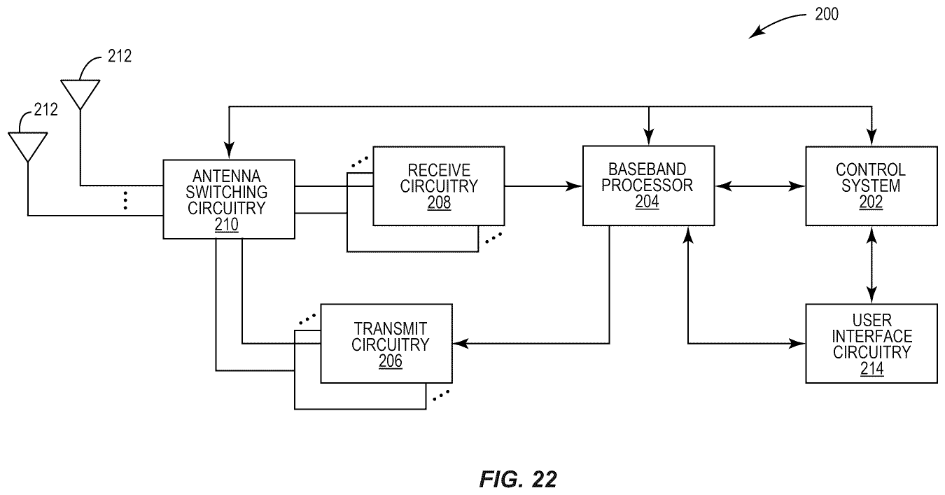

With reference to FIG. 22, the concepts described above may be implemented in various types of communication devices 200, such as those listed in the previous paragraph. The communication device 200 will generally include a control system 202, a baseband processor 204, transmit circuitry 206, receive circuitry 208, antenna switching circuitry 210, multiple antennas 212, and user interface circuitry 214. Herein, at least one or any combination of the control system 202, the baseband processor 204, the transmit circuitry 206, and the receive circuitry 208 may be implemented in the microelectronics package 100 (e.g. implemented in the first flip-chip die 124 and/or the second flip-chip die 130) described above.

In a non-limiting example, the control system 202 can be a field-programmable gate array (FPGA) or an application-specific integrated circuit (ASIC), as an example. In this regard, the control system 202 can include at least a microprocessor(s), an embedded memory circuit(s), and a communication bus interface(s). The receive circuitry 208 receives radio frequency signals via the antennas 212 and through the antenna switching circuitry 210 from one or more base stations. A low noise amplifier and a filter of the receive circuitry 208 cooperate to amplify and remove broadband interference from the received signal for processing. Down conversion and digitization circuitry (not shown) will then down convert the filtered, received signal to an intermediate or baseband frequency signal, which is then digitized into one or more digital streams using an analog-to-digital converter(s) (ADC).

The baseband processor 204 processes the digitized received signal to extract the information or data bits conveyed in the received signal. This processing typically comprises demodulation, decoding, and error correction operations, as will be discussed in greater detail below. The baseband processor 204 is generally implemented in one or more digital signal processors (DSPs) and ASICs.

For transmission, the baseband processor 204 receives digitized data, which may represent voice, data, or control information, from the control system 202, which it encodes for transmission. The encoded data is output to the transmit circuitry 206, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission and deliver the modulated carrier signal to the antennas 212 through the antenna switching circuitry 210. The multiple antennas 212 and the replicated transmit and receive circuitries 206, 208 may provide spatial diversity. Modulation and processing details will be understood by those skilled in the art.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A microelectronic package comprising:
a carrier board;
a first sub-package, which is attached to the carrier board via a plurality of electrical contacts and includes a first substrate, a first flip-chip die attached to the first substrate, and a first heat spreader attached to the first substrate and completely covering the first flip-chip die, wherein the first flip-chip die is thermally connected to the first heat spreader; and
a second sub-package, which is vertically stacked with and thermally connected to the first heat spreader of the first sub-package, wherein:
the second sub-package includes a second substrate, a second flip-chip die attached to the second substrate, and a second heat spreader attached to the second substrate and completely covering the second flip-chip die;
the second substrate is different from the first substrate and has a higher thermal conductivity than the first substrate; and
the second flip-chip die is thermally connected to both the second substrate and the second heat spreader.

2. The microelectronic package of claim 1, wherein:
the first heat spreader includes a first lid and a first periphery fence that extends outwardly from the first lid and towards the first substrate, and surrounds the first flip-chip die; and
the second heat spreader includes a second lid and a second periphery fence that extends outwardly from the second lid and towards the second substrate, and surrounds the second flip-chip die.

3. The microelectronic package of claim 2, wherein:
the first flip-chip die is attached to a top surface of the first substrate, while the first lid of the first heat spreader is formed over and thermally attached to a backside of the first flip-chip die, and the first periphery fence extends outwardly from a periphery of a bottom surface of the first lid and is attached to the top surface of the first substrate; and
a top surface of the first sub-package is a top surface of the first lid of the first heat spreader and is thermally connected to a bottom surface of the second sub-package.

4. The microelectronic package of claim 3, wherein:
the second flip-chip die is attached to a top surface of the second substrate, while the second lid of the second heat spreader is formed over and thermally attached to a backside of the second flip-chip die, and the second periphery fence extends outwardly from a periphery of a bottom surface of the second lid and is attached to the top surface of the second substrate; and
the bottom surface of the second sub-package is a bottom surface of the second substrate.

5. The microelectronic package of claim 4, wherein:
the bottom surface of the first lid of the first heat spreader is thermally attached to the backside of the first flip-chip die via a first sintered layer;
the bottom surface of the second lid of the second heat spreader is thermally attached to the backside of the second flip-chip die via a second sintered layer; and
the second periphery fence of the second heat spreader is attached to the top surface of the second substrate via a sintered component, wherein each of the first sintered layer, the second sintered layer, and the sintered component has a thermal conductivity larger than 60 W/m·K.

6. The microelectronic package of claim 3, wherein:
the second flip-chip die is attached to a bottom surface of the second substrate, while the second lid of the second heat spreader is formed underneath and thermally attached to a backside of the second flip-chip die, and the second periphery fence extends outwardly from a periphery of a top surface of the second lid and is attached to the bottom surface of the second substrate; and
the bottom surface of the second sub-package is a bottom surface of the second lid of the second heat spreader.

7. The microelectronic package of claim 6, wherein:
the bottom surface of the first lid of the first heat spreader is thermally attached to the backside of the first flip-chip die via a first sintered layer;
the top surface of the second lid of the second heat spreader is thermally attached to the backside of the second flip-chip die via a second sintered layer; and
the second periphery fence of the second heat spreader is attached to the bottom surface of the second substrate via a sintered component, wherein each of the first sintered layer, the second sintered layer, and the sintered component has a thermal conductivity larger than 60 W/m·K.

8. The microelectronic package of claim 3, wherein:
the first substrate includes a substrate body formed of one or more organic materials, and a plurality of thermal substrate vias extending through the substrate body;
each of the plurality of thermal substrate vias is connected to a corresponding one of the plurality of electrical contacts;
the bottom surface of the first lid of the first heat spreader is thermally attached to the backside of the first flip-chip die via a first sintered layer; and
the first periphery fence of the first heat spreader is thermally attached to the plurality of thermal substrate vias of the first substrate via a sintered component, wherein each of the first sintered layer and the sintered component has a thermal conductivity larger than 60 W/m·K.

9. The microelectronic package of claim 2, wherein:
the first periphery fence of the first heat spreader is composed of multiple discreate heat spreader legs with gaps in between; and
the second periphery fence of the second heat spreader is composed of multiple discreate heat spreader legs with gaps in between.

10. The microelectronic package of claim 9 further comprising a mold compound, wherein:
the mold compound is formed over the first substrate and surrounds the first heat spreader and the second sub-package; and
the mold compound fills cavities between the first flip-chip die and the first heat spreader, and between the second flip-chip die and the second heat spreader.

11. The microelectronic package of claim 2, wherein:
the first periphery fence is a continuous heat spreader wall, and the first flip-chip die is encapsulated by the first heat spreader; and
the second periphery fence is a continuous heat spreader wall, and the second flip-chip die is encapsulated by the second heat spreader.

12. The microelectronic package of claim 11 further comprising a mold compound, wherein:
the mold compound is formed over the first substrate and surrounds the first heat spreader and the second sub-package; and
the mold compound is not in contact with the first flip-chip die or the second flip-chip die.

13. The microelectronic package of claim 1, wherein the second sub-package is thermally connected to the first heat spreader of the first sub-package via a package sintered layer with a thermal conductivity larger than 60 W/m·K.

14. The microelectronic package of claim 1, wherein the first heat spreader and the second heat spreader are formed of silicon carbide.

15. The microelectronic package of claim 1, wherein:
the first heat spreader is at least 1.5 times larger than the first flip-chip die in horizontal dimensions; and
the second heat spreader is at least 1.5 times larger than the second flip-chip die in horizontal dimensions.

16. The microelectronic package of claim 1, wherein:
the first substrate is a laminate-based substrate; and
the second substrate is a lead frame substrate.

17. The microelectronic package of claim 1, wherein the plurality of electrical contacts is configured as a Ball Grid Array (BGA).

18. The microelectronic package of claim 1, wherein the plurality of electrical contacts is configured as a Land Grid Array (LGA).

19. The microelectronic package of claim 1, wherein:
the first flip-chip die includes a first die body, first interconnects extending outwardly from the first die body and coupled to the first substrate via first solder caps, respectively, and first die vias extending through the first die body and coupled to corresponding first interconnects, respectively; and
the second flip-chip die includes a second die body, second interconnects extending outwardly from the second die body and coupled to the second substrate via second solder caps, respectively, and second die vias extending through the second die body and coupled to corresponding second interconnects, respectively.

20. The microelectronic package of claim 19, wherein:
the first die body comprises gallium nitride (GaN), gallium arsenide (GaAs), or silicon; and
the second die body comprises GaN or GaAs.

21. The microelectronic package of claim 19, wherein:
the first sub-package further comprises a first underfilling material, which at least encapsulates each of the first solder caps; and
the second sub-package further comprises a second underfilling material, which at least encapsulates each of the second solder caps.

22. The microelectronic package of claim 1 further comprising a heat sink, which resides over and is thermally connected to the second sub-package.

23. A communication device comprising:
a control system;
a baseband processor;
receive circuitry; and
transmit circuitry, wherein at least one or any combination of the control system, the baseband processer, the transmit circuitry, and the receive circuitry is implemented in a microelectronic package, which has a carrier board, a first sub-package, and a second sub-package, wherein:
the first sub-package is attached to the carrier board via a plurality of electrical contacts and includes a first substrate, a first flip-chip die attached to the first substrate, and a first heat spreader attached to the first substrate and completely covering the first flip-chip die, wherein the first flip-chip die is thermally connected to the first heat spreader;
the second sub-package is vertically stacked with and thermally connected to the first heat spreader of the first sub-package;
the second sub-package includes a second substrate, a second flip-chip die attached to the second substrate, and a second heat spreader attached to the second substrate and completely covering the second flip-chip die;
the second substrate is different from the first substrate and has a higher thermal conductivity than the first substrate; and
the second flip-chip die is thermally connected to both the second substrate and the second heat spreader.

24. A method of fabricating a microelectronic package comprising:
forming a first sub-package, wherein:
the first sub-package includes a first substrate, a first flip-chip die attached to the first substrate, and a first heat spreader attached to the first substrate and completely covering the first flip-chip die; and
the first flip-chip die is thermally connected to the first heat spreader;
forming a second sub-package, wherein:
the second sub-package includes a second substrate, a second flip-chip die attached to the second substrate, and a second heat spreader attached to the second substrate and completely covering the second flip-chip die;
the second substrate is different from the first substrate and has a higher thermal conductivity than the first substrate; and
the second flip-chip die is thermally connected to both the second substrate and the second heat spreader; and
attaching the second sub-package over the first sub-package, wherein the second sub-package is thermally connected to the first heat spreader of the first sub-package.
